(19) United States
(12) Patent Application Publication
(10) Pub. No.: US 2026/0284764 A1
(43) Pub. Date: Sep. 24, 2026

(54) WIRE ELECTRICAL DISCHARGE MACHINING APPARATUS, WIRE ELECTRICAL DISCHARGE MACHINING METHOD, AND WAFER MANUFACTURING METHOD

(71) Applicant: MITSUBISHI ELECTRIC CORPORATION, Tokyo (JP)

(72) Inventor: Hidetaka MIYAKE, Tokyo (JP)

(73) Assignee: MITSUBISHI ELECTRIC CORPORATION, Tokyo (JP)

(21) Appl. No.: 19/477,507

(22) PCT Filed: May 23, 2023
(86) PCT No.: PCT/JP2023/019205

§ 371 Date: Oct. 22, 2025

(51) Int. Cl. B23H 7/20; B23H 7/16; B23H 7/18; H10P 72/00

(52) U.S. Cl. CPC B23H 7/20; B23H 7/16; B23H 7/18; H10P 72/0428; B23H 2400/10; B23H 2500/20

(57) ABSTRACT

A wire electrical discharge machining apparatus includes: wire parallel guide rollers disposed so as to sandwich the workpiece, in each of which wire guide grooves are formed on an outer peripheral side surface at equal intervals, the wire guide grooves causing cutting wire parts to fit therein and restricting movement of the cutting wire parts; parallel wire extension position measurement units measuring a distance between a reference surface and a wire electrode constituting the cutting wire parts; a wire guide groove detachment detection unit that detects a change in the distance; and a wire state determination unit that determines whether a state where at least one of the cutting wire parts is detached from the wire guide groove or a state where all the cutting wire parts are in contact with the wire guide grooves, based on the change.

### FIELD

The present disclosure relates to a wire electrical discharge machining apparatus that performs electrical discharge machining in which a plurality of plate members are collectively cut out from a workpiece using a wire electrode, a wire electrical discharge machining method, and a wafer manufacturing method.

### BACKGROUND

In a multi-wire electrical discharge machining apparatus, electrical discharge is generated between a plurality of wire electrodes and a workpiece, and a plurality of plate members are collectively cut out from the workpiece. The multi-wire electrical discharge machining apparatus is used, for example, in a semiconductor manufacturing step, for slicing in which a plurality of wafers are cut out from an ingot. A delayed detection of anomaly occurring near an electrode of the multi-wire electrical discharge machining apparatus causes various defects such as instability of electrical discharge machining, disconnection of a wire electrode, variation in the thickness of plate members to be cut out, and deterioration in surface accuracy of the plate members. For this reason, various anomaly detection techniques for a multi-wire electrical discharge machining apparatus have been developed.

Patent Literature 1 describes a multi-wire electrical discharge machining apparatus including a high-frequency pulse power supply unit and a control means. In order to detect a short circuit, the high-frequency pulse power supply unit applies a high-frequency pulse voltage to parallel wire parts and a base and includes a short-circuit determination means that determines a short circuit between wires of the parallel wire parts and a workpiece. The short-circuit determination means determines that a short circuit has occurred in a case where a time between the start of application of the high-frequency pulse voltage and the start of increase in a value of a current flowing between any of the wires and the workpiece is less than or equal to a predetermined reference.

### CITATION LIST

### Patent Literature

Patent Literature 1: Japanese Patent Application Laid-open No. 2017-87395 (JP 2017-87395 A)

### SUMMARY OF INVENTION

### Problem to be Solved by the Invention

A multi-wire electrical discharge machining apparatus may be provided with a pair of guide rollers disposed on both sides of a workpiece with the workpiece interposed therebetween in order to prevent positional displacement of a cutting wire so that a separation distance between a plurality of cutting wires disposed in parallel does not change from the start of machining to the end of machining. In that case, a plurality of wire guide grooves defining the separation distance between a plurality of wire electrodes disposed in parallel are machined on surfaces of the guide rollers.

Regarding a plurality of wire electrodes running in parallel for collectively cutting out a plurality of plate members from the workpiece, any of the wire electrodes may rise from the wire quide groove. Examples of a factor that causes the rising of the wire electrode include a machining fluid flow supplied between the electrodes during machining, a repulsive force of electrical discharge, eccentricity during rotation of a guide mechanism in which wire guide grooves for disposing the wire electrodes in parallel at intervals determined by the thickness of the plate members to be cut out are formed on a cylindrical side surface, and foreign matter accumulated in the wire guide grooves.

The wire electrode that has risen from the wire guide groove may deviate from the wire guide groove due to the external force exemplified above, or the like. As a result, the plurality of wire electrodes cannot run at a predetermined parallel interval, the thickness of the plate members cut out from the ingot becomes uneven, and the productivity of the plate members decreases.

In addition, the wire electrode detached from the wire guide groove becomes unstable in parallel running, which results in unstable electrical discharge machining, and thus the disconnection of the wire electrode is likely to occur. Furthermore, in a case where the disconnection of the wire electrode occurs and the disconnected wire electrode is reconnected to continue the electrical discharge machining, a machined groove that has been formed is a groove machined by the wire electrode running off the wire guide groove, and deviates from an original position formed by the wire electrode disposed in parallel, so that it is difficult to resume the electrical discharge machining from a position of the disconnection. Therefore, detection of an anomaly is important in the multi-wire electrical discharge machining apparatus.

However, the multi-wire electrical discharge machining apparatus described in Patent Literature 1 detects an anomaly on the basis of a current value between the electrodes, so that it is not possible to detect a defect that does not appear in the current value, and it is not possible to accurately detect a defect caused by positional displacement of a wire electrode, which is problematic.

The present disclosure has been made in view of the above, and an object thereof is to provide a wire electrical discharge machining apparatus capable of accurately detecting a defect caused by positional displacement of a wire electrode.

### Means to Solve the Problem

In order to solve the above-described problems and achieve the object, a wire electrical discharge machining apparatus according to the present disclosure generates electrical discharge between a plurality of cutting wire parts that are running and a workpiece to perform electrical discharge machining on the workpiece with energy generated by the electrical discharge, and simultaneously cuts a plurality of wafers from the workpiece. The wire electrical discharge machining apparatus includes: a wire electrode including the plurality of the cutting wire parts spaced apart from each other in parallel and including a portion facing the workpiece; a power feed unit to generate electrical discharge between the plurality of cutting wire parts and the workpiece; a pair of wire parallel guide rollers disposed on both sides of the workpiece so as to sandwich the workpiece, in each of which a plurality of wire guide grooves are formed on an outer peripheral side surface thereof at equal intervals, the plurality of wire guide grooves causing the plurality of cutting wire parts that are running to fit therein and restricting movement of the plurality of cutting wire parts; and a parallel wire extension position measurement unit to measure a distance between a measurement reference surface set parallel to a virtual plane including the plurality of cutting wire parts and the wire electrode constituting the plurality of cutting wire parts. The wire electrical discharge machining apparatus includes: a wire guide groove detachment detection unit to detect occurrence of a change in the distance on a basis of a measurement result obtained by the parallel wire extension position measurement unit; a wire state determination unit to determine whether it is a wire detachment state where at least one of the cutting wire parts is detached from the wire guide groove or a wire contact state where all the cutting wire parts are in contact with the wire quide grooves, on a basis of a detection result obtained by the wire guide groove detachment detection unit; and a machining control unit to control stop or continuation of electrical discharge machining on a basis of a determination result obtained by the wire state determination unit.

### Effects of the Invention

The present disclosure achieves an effect that it is possible to provide a wire electrical discharge machining apparatus capable of accurately detecting a defect caused by positional displacement of a wire electrode.

### BRIEF DESCRIPTION OF DRAWINGS

FIG. 1 is a conceptual diagram illustrating an exemplary configuration of a wire electrical discharge machining apparatus according to a first embodiment.

FIG. 2 is a schematic diagram illustrating an exemplary configuration of a wire extension state monitoring unit of the wire electrical discharge machining apparatus according to the first embodiment.

FIG. 3 is a perspective view illustrating an exemplary installation of a parallel wire extension position measurement unit with respect to cutting wire parts in the wire electrical discharge machining apparatus according to the first embodiment.

FIG. 4 is a block diagram illustrating exemplary configurations of a control unit and the wire extension state monitoring unit included in the wire electrical discharge machining apparatus according to the first embodiment.

FIG. 5 is a diagram illustrating a positional relationship among a wire parallel guide roller, parallel wire parts, and a guide roller holder in the wire electrical discharge machining apparatus according to the first embodiment.

FIG. 6 is a schematic diagram illustrating the parallel wire parts extended in a plurality of wire guide grooves in the wire parallel guide roller included in the wire electrical discharge machining apparatus according to the first embodiment.

FIG. 7 is a first schematic diagram illustrating an example of a state where the parallel wire part is detached from the wire guide groove in the wire parallel guide roller included in the wire electrical discharge machining apparatus according to the first embodiment.

FIG. 8 is a second schematic diagram illustrating an example of the state where the parallel wire part is detached from the wire guide groove in the wire parallel guide roller included in the wire electrical discharge machining apparatus according to the first embodiment.

FIG. 9 is a diagram illustrating an example of a detection value of a wire guide groove detachment detection unit in the state illustrated in FIG. 6.

FIG. 10 is a diagram illustrating an example of a detection value of the wire guide groove detachment detection unit in the state illustrated in FIG. 7.

FIG. 11 is a diagram illustrating an example of a detection value of the wire guide groove detachment detection unit in the state illustrated in FIG. 8.

FIG. 12 is a flowchart illustrating an operation of the wire electrical discharge machining apparatus according to the first embodiment during cutting.

FIG. 13 is a schematic diagram illustrating an exemplary configuration of a wire contact machining state monitoring unit of the wire electrical discharge machining apparatus in a second embodiment.

FIG. 14 is a block diagram illustrating exemplary configurations of the control unit and the wire contact machining state monitoring unit included in the wire electrical discharge machining apparatus in the second embodiment.

FIG. 15 is a characteristic diagram illustrating a timing of switching between machining voltage application and wire contact detection of the wire electrical discharge machining apparatus in the second embodiment.

FIG. 16 is a schematic diagram illustrating an example of a state where the parallel wire part is detached from the wire guide groove in the wire parallel guide roller of the wire electrical discharge machining apparatus in the second embodiment.

FIG. 17 is a conceptual diagram illustrating a detection value corresponding to the wire detachment state in FIG. 16 and determination of a state corresponding to the detection value.

FIG. 18 is a diagram illustrating a configuration in which each function of the control unit according to the first and second embodiments is realized by hardware.

FIG. 19 is a diagram illustrating a configuration in which each function of the control unit according to the first and second embodiments is realized by software.

### DESCRIPTION OF EMBODIMENTS

Hereinafter, a wire electrical discharge machining apparatus, a wire electrical discharge machining method, and a wafer manufacturing method according to each embodiment will be described in detail with reference to the drawings.

### First Embodiment

A multi-wire electrical discharge machining apparatus is used, for example, in a semiconductor manufacturing step, for slicing in which a plurality of semiconductor wafers are collectively cut out from an ingot, that is, collective cutting of the plurality of semiconductor wafers. In the multi-wire electrical discharge machining apparatus, thin plates to be collectively cut are cut by electrical discharge generated between a workpiece and a plurality of cutting wire parts spaced apart from each other in parallel and facing the workpiece. Therefore, in the multi-wire electrical discharge machining apparatus, a separation distance between the cutting wire parts disposed in parallel greatly affects the thickness of the thin plates to be cut out.

Therefore, the multi-wire electrical discharge machining apparatus is provided with a pair of wire parallel guide rollers disposed on both sides of the workpiece with the workpiece interposed therebetween in order to prevent positional displacement of a plurality of cutting wire parts disposed in parallel so that a separation distance between the cutting wire parts does not change from the start of machining to the end of machining.

A plurality of wire guide grooves in a V-groove shape defining the separation distance between respective wire electrode parts are machined on the surfaces of the wire parallel guide rollers. Wire electrodes disposed one by one with respect to each of the wire guide grooves are extended between the pair of wire parallel guide rollers to form the cutting wire parts.

The wire guide grooves are formed on the surface of each wire parallel guide roller at an interval designed for cutting out thin plates to be collectively cut with a desired plate thickness. During electrical discharge cutting, the pair of wire parallel guide rollers causes the cutting wire parts to run in parallel while constraining the plurality of wire electrodes so that a distance between the plurality of wire electrodes is maintained.

In thin plate machining by the multi-wire electrical discharge machining apparatus, a machining fluid is ejected from a nozzle toward a machined groove along an extension direction of a cutting wire. In a case where a columnar ingot is cut, the flow rate of the machining fluid is adjusted correspondingly to a cutting thickness. However, adjustment of the flow rate of the machining fluid is a factor in vibration applied to the wire electrodes and a factor in tension fluctuations of the wire electrodes. In addition, when electrical discharge energy is increased in order to speed up the electrical discharge cutting, a repulsive force due to electrical discharge increases. The increase in the repulsive force due to electrical discharge is similarly a factor in the vibration applied to the wire electrodes and a factor in the tension fluctuations of the wire electrodes. Alternatively, foreign matter such as a machining debris generated during cutting is interposed in the wire guide groove of the wire parallel guide roller, resulting that the corresponding part of the wire electrode is locally in a shallow state due to the foreign matter in the wire guide groove.

In addition, the wire electrodes are pushed out in a direction opposite to a direction of a machined surface of the ingot and bent by an impact force of electrical discharge. The direction of the machined surface of the ingot is a machining progression direction of the ingot by the wire electrodes, and is a cutting progression direction of the ingot by the wire electrodes. The direction opposite to the direction of the machined surface of the ingot can be said to be an anti-machining progression direction or an anti-cutting progression direction. That is, the wire electrodes are pushed out in the anti-machining progression direction and bent by the impact force of electrical discharge. The impact force of electrical discharge that pushes out the wire electrodes in the anti-machining progression direction is referred to as an electrical discharge repulsive force.

The wire electrode is pressed against not a deepest portion of the wire guide groove but an inclined surface on one side of the wire guide groove in a V-groove shape due to the various disturbances described above, and furthermore, the wire electrode is detached from the wire guide groove and rides on the outer peripheral surface of the wire parallel guide roller at a portion between the wire guide groove itself and a wire quide groove adjacent thereto, and in that state, the wire electrode continues running. As a result, when the electrical discharge cutting by the cutting wire parts progresses, there occurs a region where the plate thickness rapidly changes in the thin plates machined thereafter, and thus it is not possible to perform collective cutting of thin plates having uniform plate thickness.

In a case of a semiconductor wafer, cracking or chipping that occurs even in a part of the semiconductor wafer results in a problem such as a decrease in yield in a polishing step of a sliced semiconductor wafer or a semiconductor manufacturing process after the polishing step. Therefore, cracking or chipping of a semiconductor wafer is a factor in significant loss of a commercial value of the semiconductor wafer.

That is, in the electrical discharge cutting in which a plurality of plate members are collectively cut from the workpiece by using the wire electrodes, the flow rate of the machining fluid supplied to a gap between the thin plates being formed is increased in order to improve evacuation of machining debris generated by electrical discharge and cooling of wires heated by electrical discharge energy, and thereby the pressure of a machining fluid flow received by each wire electrode is increased and thus the wire electrode is shaken. In addition, the wire electrode is shaken by an electrical discharge repulsive force proportional to the electrical discharge energy. Moreover, the wire electrode is shaken by machining debris accumulated in the wire guide groove of the wire parallel guide roller or debris clogged in the wire guide groove. The wire electrode shaken as described above in the middle of machining is detached from a constraining position at the deepest portion in the wire quide groove in a V-groove shape, which causes, in the middle of machining, the wire electrode to cut the workpiece at a parallel interval different from a design value.

At the position where the positional displacement of the wire electrode occurs, the machined groove formed in the workpiece is deflected from the position of the machined groove that has been designed, and the positional displacement of the machined groove occurs. The portion where the positional displacement of the machined groove has occurred causes a resistance to inflow and outflow of the machining fluid supplied into the machined groove, and the machining fluid in the machined groove is less likely to be replaced. As a result, in the electrical discharge cutting after the occurrence of the positional displacement of the wire electrode, the machining state becomes unstable, the electrical discharge cutting performance deteriorates, the plate thickness of the thin plates tends to be uneven, and the wire disconnection is likely to occur.

For example, in a case where the workpiece is an ingot made of a crystal of silicon carbide (Sic) and an ingot made of a crystal of gallium nitride (GaN), when the diameter thereof increases, and thus a diameter dimension of the semiconductor wafer increases, a distance between the installed pair of parallel wire guide rollers increases accordingly. Therefore, the wire electrode is more likely to bend, and the detachment of the wire electrode from the wire guide groove of the wire parallel guide roller is more likely to occur.

Hereinafter, the thin plate cut and separated by the cutting process is referred to as a wafer.

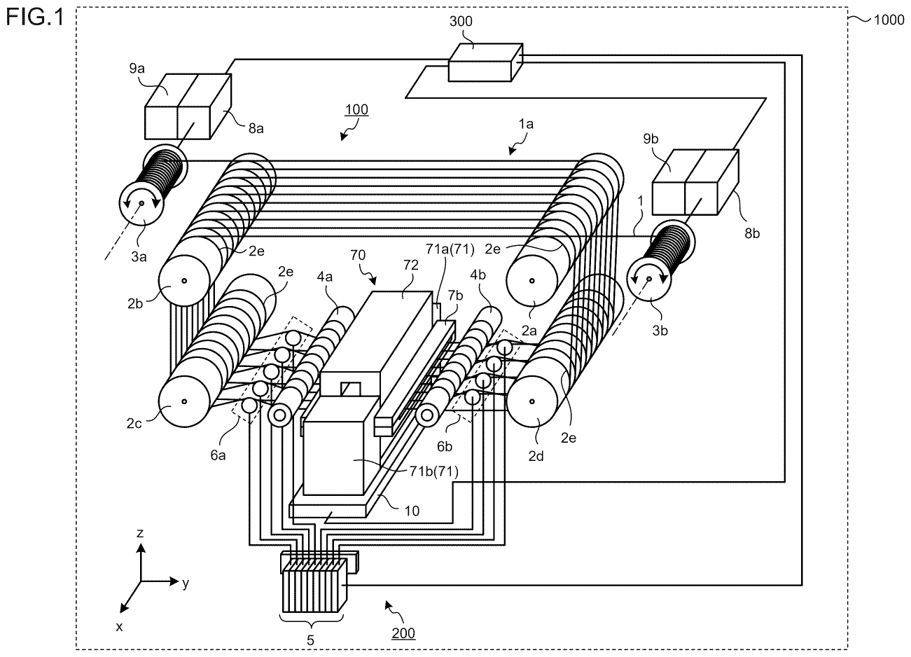

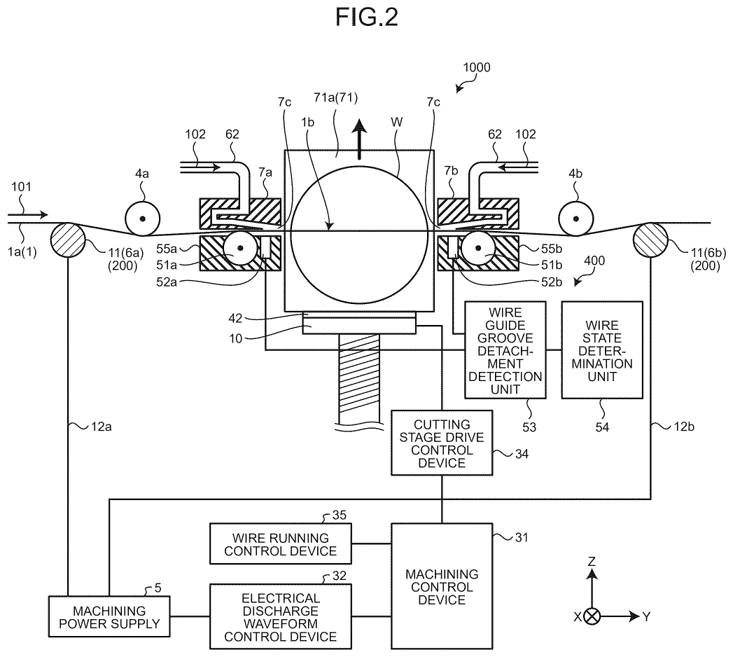

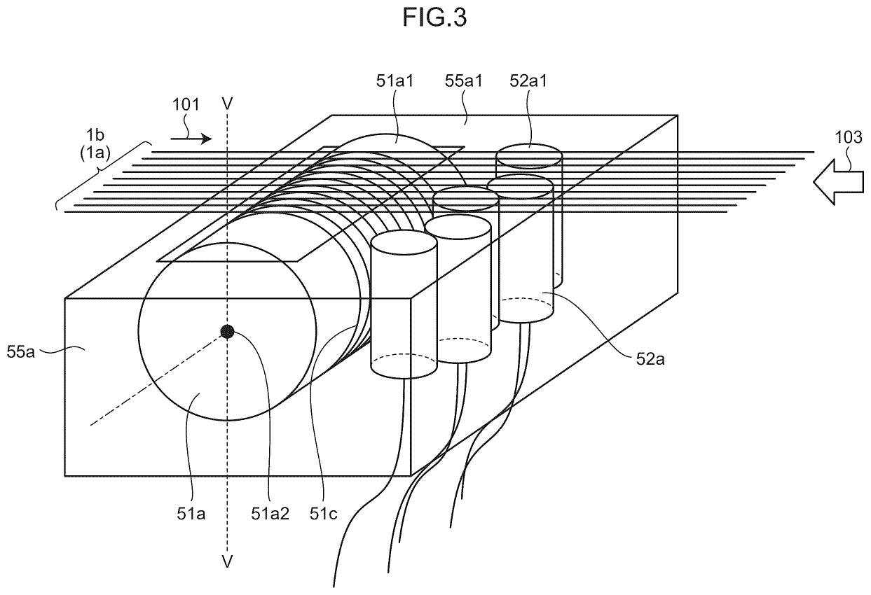

FIG. 1 is a conceptual diagram illustrating an exemplary configuration of a wire electrical discharge machining apparatus 1000 according to a first embodiment. FIG. 2 is a schematic diagram illustrating an exemplary configuration of a wire extension state monitoring unit 400 of the wire electrical discharge machining apparatus 1000 according to the first embodiment. FIG. 2 illustrates a positional relationship among a workpiece W, wire parallel guide rollers 51a and 51b, guide roller holders 55a and 55b, nozzles 7a and 7b, damping guide rollers 4a and 4b, and a power feed unit 200. FIG. 2 illustrates a state where the electrical discharge cutting is performed by cutting wire parts 1b, and the wire electrical discharge cutting performed on the workpiece W in a columnar shape has proceeded to a position corresponding to about ½ of the diameter of the workpiece W. In FIG. 2, a thin plate machining stabilization unit 70 is not illustrated. FIG. 3 is a perspective view illustrating an exemplary installation of a parallel wire extension position measurement unit 52a with respect to the cutting wire parts 1b in the wire electrical discharge machining apparatus 1000 according to the first embodiment. FIG. 3 illustrates a state where the cutting wire parts 1b extended between the wire parallel quide rollers 51a and 51b of the wire extension state monitoring unit 400 included in the wire electrical discharge machining apparatus 1000 pass above the guide roller holder 55a.

The wire electrical discharge machining apparatus 1000 is a multi-wire electrical discharge machining apparatus that performs electrical discharge machining by using a wire electrode 1. In FIGS. 2 and 3, an arrow 101 indicates a running direction of the cutting wire parts 1b. In FIG. 2, an arrow 102 indicates a direction of a machining fluid flow.

FIG. 1 illustrates an x axis, a y axis, and a z axis of a three-axis Cartesian coordinate system. A y-axis direction corresponds to a running direction of the wire electrode 1 on the workpiece W, that is, the running direction of the wire electrode 1 with respect to the workpiece W disposed in the wire electrical discharge machining apparatus 1000. A z-axis direction corresponds to a height direction of the wire electrical discharge machining apparatus 1000. The height direction of the wire electrical discharge machining apparatus 1000 corresponds to an upward and downward direction, that is, a vertical direction. An x-axis direction corresponds to a direction in which portions of the wire electrode 1 are disposed in parallel on the workpiece W, that is, a direction in which the portions of the wire electrode 1 are disposed in parallel with respect to the workpiece W disposed in the wire electrical discharge machining apparatus 1000. The x-axis direction can be said to be a direction parallel to a longitudinal direction of the workpiece W disposed in the Wire electrical discharge machining apparatus 1000.

The wire electrical discharge machining apparatus 1000 includes a machining mechanism unit 100 that performs electrical discharge cutting on the workpiece W with the wire electrode 1, the power feed unit 200 that executes power supply, a control unit 300 that controls the wire electrical discharge machining apparatus 1000, and the wire extension state monitoring unit 400. The wire electrical discharge machining apparatus 1000 cuts out a plurality of plate members collectively from the workpiece W. Examples of the material for the workpiece W include tungsten, molybdenum, silicon carbide, monocrystalline silicon, monocrystalline silicon carbide, gallium nitride, and polycrystalline silicon. Silicon carbide is also referred to as “Tanka Keiso” in Japanese. Hereinafter, the electrical discharge cutting may be simply referred to as cutting.

The machining mechanism unit 100 includes a plurality of guide rollers 2, bobbins 3, the damping guide rollers 4a and 4b, the nozzles 7a and 7b, bobbin rotation control devices 8a and 8b, traverse control devices 9a and 9b, and a cutting feed stage 10. The plurality of guide rollers 2 include a guide roller 2a, a guide roller 2b, a guide roller 2c, and a guide roller 2d. The bobbins 3 include a bobbin 3a and a bobbin 3b.

The plurality of guide rollers 2 quide the running of the wire electrode 1. Each of the guide rollers 2a, 2b, 2c, and 2d is installed so as to be rotatable around a rotation axis corresponding thereto. The guide rollers 2a, 2b, 2c, and 2d are disposed apart from one another, and are disposed so that rotation axes thereof are parallel to one another. Since the rotation axes of the guide rollers 2a, 2b, 2c, and 2d are parallel to one another, the wire electrode 1 can run with high accuracy. The rotation axes of the guide rollers 2a, 2b, 2c, and 2d are disposed parallel to the x axis.

One wire electrode 1 is wound a plurality of times around the quide rollers 2a, 2b, 2c, and 2d at intervals in a direction of the rotation axis of each of the guide rollers 2a, 2b, 2c, and 2d. These portions of the wire electrode 1 are collectively referred to as parallel wire parts 1a. Portions of the parallel wire parts 1a facing the workpiece W are each referred to as the cutting wire part 1b. The cutting wire parts 1b include a plurality of the parallel wire parts 1a disposed in parallel. The cutting wire parts 1b are preferably installed parallel to each other.

On the surfaces of the guide rollers 2a, 2b, 2c, and 2d, a plurality of wire guide grooves 2e are formed at equal intervals. By winding the wire electrode 1 around the surfaces of the guide rollers 2a, 2b, 2c, and 2d along the plurality of wire guide grooves 2e, the guide rollers 2a, 2b, 2c, and 2d keep the interval between the portions of the wire electrode 1, that is, the interval between the portions of the wire electrode 1 of the parallel wire parts 1a constant. In the wire electrical discharge machining apparatus 1000, the cutting wire parts 1b are disposed parallel to each other and at equal intervals, so that the plate thicknesses of the plurality of plate members cut out from the workpiece W can be made equal to one another, and the cross sections of the plurality of plate members can be made parallel to one another. Regarding the plurality of guide rollers 2, the number thereof is not necessarily four, and may be three or less, or may be five or more.

The bobbins 3a and 3b cause the wire electrode 1 to run by an operation of unwinding the wire electrode 1 and an operation of winding the wire electrode 1. The bobbin 3a performs the operation of unwinding the wire electrode 1. The bobbin 3b performs the operation of winding the wire electrode 1. The bobbin rotation control device 8a and the traverse control device 9a control the bobbin 3a. The bobbin rotation control device 8b and the traverse control device 9b control the bobbin 3b.

The bobbin rotation control device 8a controls the rotation of the bobbin 3a and controls the running of the wire electrode 1. The bobbin rotation control device 8a controls, for example, a running direction and a running speed of the wire electrode 1. The bobbin rotation control device 8b controls the rotation of the bobbin 3b and controls the running of the wire electrode 1. The bobbin rotation control device 8b controls, for example, the running direction and the running speed of the wire electrode 1.

The traverse control device 9a controls a position of the bobbin 3a in the x-axis direction correspondingly to an unwinding position of the wire electrode 1. The traverse control device 9b controls a position of the bobbin 3b in the x-axis direction correspondingly to a winding position of the wire electrode 1. The position control of the bobbins 3a and 3b by the traverse control devices 9a and 9b is referred to as traverse control. By the traverse control, the bobbins 3a and 3b can cause the wire electrode 1 to run stably and with high accuracy.

The wire electrode 1 unwound from the bobbin 3a is wound around the guide roller 2b, the quide roller 2a, the guide roller 2d, and the guide roller 2c in this order, and then the winding is continued from the guide roller 2b again. The wire electrode 1 is wound on to the bobbin 3b after circulating a plurality of times through the guide rollers 2a, 2b, 2c, and 2d in the manner as described above.

The workpiece W is placed on a workpiece fixing plate 42 fixed to the cutting feed stage 10 described later. The workpiece fixing plate 42 to which the workpiece W is fixed is disposed between the wire parallel guide roller 51a and the wire parallel guide roller 51b in the y-axis direction.

The wire parallel guide rollers 51a and 51b are disposed on both sides of the workpiece W so as to sandwich the workpiece W in the y-axis direction. The wire parallel guide rollers 51a and 51b are installed between the damping guide roller 4a and the damping guide roller 4b in the y-axis direction. The wire parallel guide rollers 51a and 51b restrict the movement of the wire electrode 1 in the x-axis direction. Specifically, the wire parallel guide rollers 51a and 51b restrict the movement of the parallel wire parts 1a and the cutting wire parts 1b in the x-axis direction.

Each of the wire parallel guide rollers 51a and 51b has a rotation axis similarly to the quide rollers 2a, 2b, 2c, and 2d, and is installed so as to be rotatable around the corresponding rotation axis. The wire parallel guide rollers 51a and 51b are disposed apart from each other in the y-axis direction, and are disposed so that rotation axes thereof are parallel to each other. Since the rotation axes of the wire parallel guide rollers 51a and 51b are parallel to each other, the wire electrode 1 can run with high accuracy. The rotation axes of the wire parallel guide rollers 51a and 51b are disposed parallel to the x axis.

On the surfaces of the wire parallel guide rollers 51a and 51b, a plurality of wire guide grooves 51c are formed at equal intervals designed in advance. By the wire electrode 1 running on the surfaces of the wire parallel guide rollers 51a and 51b along the plurality of wire guide grooves 51c, the wire parallel guide rollers 51a and 51b keep the interval between the portions of the wire electrode 1, that is, the interval between the portions of the wire electrode 1 of the parallel wire parts 1a constant. In the wire electrical discharge machining apparatus 1000, the cutting wire parts 1b are disposed parallel to each other and at equal intervals, so that the plate thicknesses of the plurality of plate members cut out from the workpiece W can be made equal to one another, and the cross sections of the plurality of plate members can be made parallel to one another.

That is, the wire parallel guide rollers 51a and 51b guide the running of the parallel wire parts 1a and the cutting wire parts 1b of the wire electrode 1 wound a plurality of times at equal intervals in the direction of the rotation axis of each of the guide rollers 2a, 2b, 2c, and 2d and running apart from each other, and reduce the vibration of the parallel wire parts 1a in a section of the cutting thickness of the workpiece W. Consequently, the wire parallel guide rollers 51a and 51b can cause the parallel wire parts 1a and the cutting wire parts 1b to run while maintaining an alignment interval of the parallel wire parts 1a and the cutting wire parts 1b with high accuracy.

As illustrated in FIG. 2, the wire parallel guide rollers 51a and 51b are supported by a pair of guide roller holders 55a and 55b provided with bearings that support the wire parallel guide rollers 51a and 51b so that the wire parallel guide rollers 51a and 51b are rotatable around the corresponding rotation axes.

The pair of guide roller holders 55a and 55b are fixed to both sides of the workpiece W so that the rotation axes of the wire parallel quide rollers 51a and 51b are disposed parallel to the x-axis direction so as to sandwich the workpiece W in the y-axis direction. As illustrated in FIG. 3, the guide roller holder 55a supports a rotation shaft 51a2 of the wire parallel quide roller 51a to support the wire parallel guide roller 51a in a state where an upper end portion 51al of the wire parallel guide roller 51a protrudes upward from an upper surface 55al of the guide roller holder 55a. Similarly, the guide roller holder 55b supports a rotation shaft of the wire parallel guide roller 51b to support the wire parallel guide roller 51b in a state where an upper end portion (not illustrated) of the wire parallel guide roller 51b protrudes upward from an upper surface (not illustrated) of the guide roller holder 55b.

The nozzle 7a is disposed between the damping guide roller 4a and the workpiece W in the y-axis direction. The nozzle 7b is disposed between the damping guide roller 4b and the workpiece W in the y-axis direction. The nozzles 7a and 7b are disposed at positions above the plurality of parallel wire parts 1a in a state where the plurality of parallel wire parts 1a are sandwiched between the wire parallel guide rollers 51a and 51b and the nozzle 7a and 7b, respectively, and in a state where the nozzle 7a and 7b are spaced apart from the plurality of parallel wire parts 1a in the z-axis direction. The inside of the nozzles 7a and 7b is filled with the machining fluid supplied from a machining fluid supply pipe 62. The nozzles 7a and 7b each include a machining fluid ejection hole 7c through which the machining fluid filled in the nozzles 7a and 7b is ejected toward the workpiece W in the thin plate machining stabilization unit 70. The parallel wire parts 1a run below the machining fluid ejection holes 7c of the nozzles 7a and 7b.

A machining fluid tank and a pump may be connected to the nozzles 7a and 7b. The thin plate machining stabilization unit 70 to which the workpiece W is fixed may be installed inside a machining vessel in which the machining fluid is stored, and the electrical discharge machining may be executed while the workpiece W is immersed in the machining fluid.

In the wire electrical discharge machining apparatus 1000, the wire parallel quide rollers 51a and 51b restrict the movement of the wire electrode 1 in the x-axis direction, and furthermore, the damping guide rollers 4a and 4b restrict the movement of the wire electrode 1 in the z-axis direction, thereby reducing the vibration of the wire electrode 1 in the cutting wire parts 1b. Although the portions of the parallel wire parts 1a facing the workpiece W are referred to as the cutting wire parts 1b as described above, portions of the parallel wire parts 1a above the wire parallel guide roller 51a and above the wire parallel guide roller 51b, and portions thereof between the wire parallel guide roller 51a and the wire parallel guide roller 51b are also referred to as the cutting wire parts 1b. In the wire electrical discharge machining apparatus 1000, the damping guide roller 4a and the damping guide roller 4b can be omitted.

The cutting feed stage 10 changes relative positions of the workpiece W and the cutting wire parts 1b. Specifically, the cutting feed stage 10 changes relative positions of the workpiece fixing plate 42 to which the workpiece W is fixed and the cutting wire parts 1b. In the first embodiment, the positions of the cutting wire parts 1b in the z-axis direction are fixed, and the cutting feed stage 10 is movable in the z-axis direction. The cutting feed stage 10 moves the workpiece W in the upward and downward direction. By the movement of the cutting feed stage 10 in the upward and downward direction, the wire electrical discharge machining apparatus 1000 causes the workpiece W to relatively approach or separate from the cutting wire parts 1b, thereby cutting the workpiece W. In addition, a machined groove along each of the cutting wire parts 1b is formed in the workpiece W by the electrical discharge machining on the workpiece W. Note that the cutting feed stage 10 may be movable in the x-axis direction, the y-axis direction, and the z-axis direction.

The machining mechanism unit 100 may include components such as a guide pulley that reduces vibration of the wire electrode 1, a load cell that measures tension of the wire electrode 1, and a dancer roller that controls tension of the wire electrode 1. The machining mechanism unit 100 may maintain the tension of the wire electrode 1 in a range suitable for running of the wire electrode 1 by the load cell and the dancer roller. For example, the dancer roller may control the tension of the wire electrode 1 by changing an unwinding speed and a winding speed of the wire electrode 1.

The power feed unit 200 includes a machining power supply 5 and power feed contact units 6a and 6b. The machining power supply 5 supplies power to the wire electrode 1 via the power feed contact units 6a and 6b connected to the wire electrode 1. The machining power supply 5 also supplies power to the workpiece W via the machining fluid flow rectifying plate 71a described later. The power feed contact units 6a and 6b, which are power feeding means, are an assembly of a plurality of power feed contacts 11. The power feed contacts 11 are insulated from each other. Each of the portions of the wire electrode 1 of the cutting wire parts 1b is supplied with power from the power feed contact 11, and a machining current flows therethrough. In the machining power supply 5 which is a power supply means, a power supply-side terminal is electrically connected to each of the power feed contact units 6a and 6b, and a ground-side terminal is electrically connected to the workpiece W. Therefore, a voltage pulse output from the machining power supply 5 is applied between the portions of the wire electrode 1 of the cutting wire parts 1b and the workpiece W. The machining power supply 5, the plurality of power feed contacts 11, and a workpiece W5 are electrically connected by power supply lines 12.

The thin plate machining stabilization unit 70 is a mechanism unit that prevents power supply failure to each thin plate during cutting. The thin plate machining stabilization unit 70 is disposed between the damping guide roller 4a and the damping guide roller 4b and between the nozzle 7a and the nozzle 7b. The thin plate machining stabilization unit 70 includes the machining fluid flow rectifying plate 71a and a machining fluid flow rectifying plate 71b which are a pair of machining fluid flow rectifying plates 71, and a workpiece retaining unit 72.

The machining fluid flow rectifying plate 71a and the machining fluid flow rectifying plate 71b which are the pair of machining fluid flow rectifying plates 71 have conductivity, are disposed parallel to the running direction of the cutting wire parts 1b, and rectify the flow of the machining fluid. The machining fluid flow rectifying plate 71a and the machining fluid flow rectifying plate 71b are disposed between the nozzle 7a and the nozzle 7b. The machining fluid flow rectifying plate 71a and the machining fluid flow rectifying plate 71b have a plate shape or a rectangular parallelepiped shape, and are disposed so that surfaces thereof that face each other are in parallel.

The machining fluid flow rectifying plate 71a is a first machining fluid flow rectifying plate of the pair of machining fluid flow rectifying plates 71, and is connected to the machining power supply 5. Consequently, electrical discharge machining power is supplied to the workpiece W from the machining fluid flow rectifying plate 71a which is in contact with an end surface of the workpiece W.

The machining fluid flow rectifying plate 71b is a second machining fluid flow rectifying plate of the pair of machining fluid flow rectifying plates 71, and is disposed parallel to the machining fluid flow rectifying plate 71a in a state where the workpiece W fixed to the workpiece fixing plate 42 is sandwiched between the machining fluid flow rectifying plate 71a and the machining fluid flow rectifying plate 71b.

The machining fluid flow rectifying plate 71b is in close contact with the workpiece W, and forms, together with the machining fluid flow rectifying plate 71a, a flow path for guiding the machining fluid supplied from the nozzles 7a and 7b to the workpiece W. The machining fluid is supplied from the nozzles 7a and 7b to a gap between the machining fluid flow rectifying plate 71a and the machining fluid flow rectifying plate 71b, toward the workpiece W. Consequently, the diffusion of the machining fluid in the thickness direction of the thin plates being formed, that is, in the x-axis direction is reduced.

In the wire electrical discharge machining apparatus 1000, since the flow of the machining fluid supplied from the nozzles 7a and 7b is rectified as described above, the diffusion of the machining fluid is reduced, which decreases a possibility that the thin plates being formed are shaken by the machining fluid and cracked.

The workpiece W is sandwiched between the machining fluid flow rectifying plate 71a and the machining fluid flow rectifying plate 71b, and is placed on the workpiece fixing plate 42 and fixed thereto inside the thin plate machining stabilization unit 70. The workpiece W is fixed onto the workpiece fixing plate 42 by a jig (not illustrated) for fixing the workpiece W, which is placed on the cutting feed stage 10.

In a case where the workpiece W is a material for a semiconductor wafer, the shape of the workpiece W is often formed into a columnar shape in advance so that thin plates after cutting become circular thin plates. Here, regarding the workpiece W having a columnar shape, a side surface of the column that forms a curved surface is referred to as an outer peripheral side surface. The workpiece W is disposed on the workpiece fixing plate 42 inside the thin plate machining stabilization unit 70 so that the outer peripheral side surface faces the cutting wire parts 1b. By slicing the workpiece W by using the cutting wire parts 1b, wafers which are thin plates are machined from the workpiece W.

When a voltage of a certain value is applied between electrodes, i.e., a gap between the cutting wire parts 1b and the workpiece W, and an inter-electrode distance reaches a value in a certain range, electrical discharge is generated between the electrodes, which causes generation of heat in the cutting wire parts 1b, leading to melting of the workpiece W. As a result, a plurality of plate members are collectively cut out. When the machining fluid is supplied to the gap between the workpiece W and the cutting wire parts 1b during cutting, machining debris generated between the workpiece W and the cutting wire parts 1b can be discharged outside the gap. Even though the machining debris may cause a short circuit between the workpiece W and the cutting wire parts 1b, the frequency of occurrence of short circuits can be reduced by supplying the machining fluid.

The workpiece retaining unit 72 retains the plurality of thin plates being formed from an outer peripheral side surface side on a cutting start portion side of the plurality of thin plates, and collectively fixes the plurality of thin plates being formed. By collectively fixing the plurality of thin plates being formed, the workpiece retaining unit 72 can reduce shaking of the plurality of thin plates due to vibration of the workpiece W generated by fluid pressure of the machining fluid flow received by cut surfaces of the plurality of thin plates.

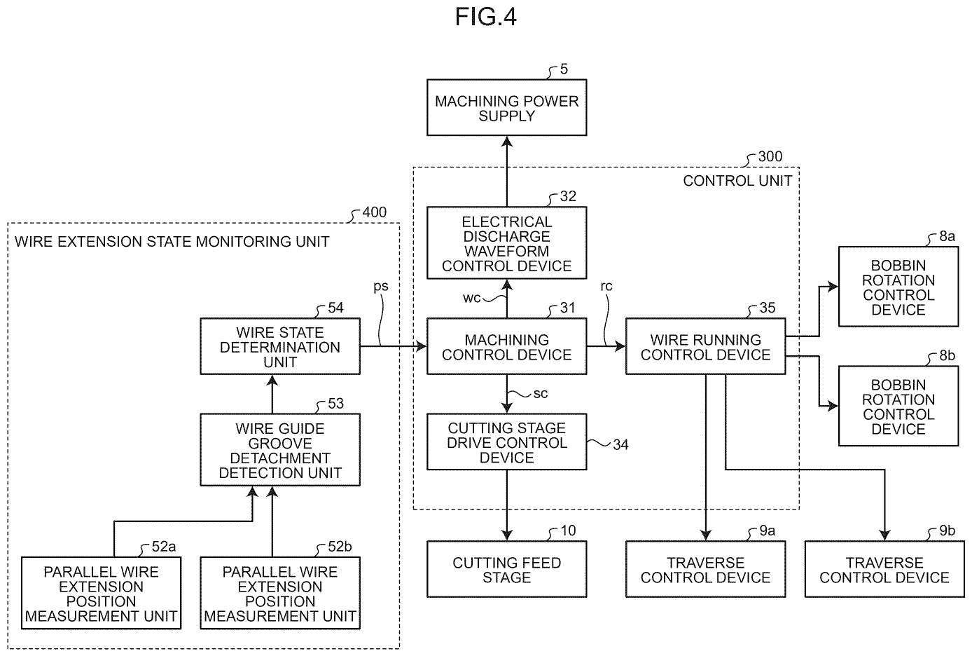

The wire extension state monitoring unit 400 monitors an extension state of the parallel wire parts 1a during cutting. FIG. 4 is a block diagram illustrating exemplary configurations of the control unit 300 and the wire extension state monitoring unit 400 included in the wire electrical discharge machining apparatus 1000 according to the first embodiment. The wire extension state monitoring unit 400 includes parallel wire extension position measurement units 52a and 52b, a wire guide groove detachment detection unit 53, and a wire state determination unit 54. The parallel wire extension position measurement units 52a and 52b are connected to the wire guide groove detachment detection unit 53. The wire guide groove detachment detection unit 53 is connected to the wire state determination unit 54. The wire state determination unit 54 is connected to a machining control device 31 of the control unit 300. The wire extension state monitoring unit 400 for the cutting wire parts 1b is thus configured.

As illustrated in FIGS. 2 and 3, the pair of parallel wire extension position measurement units 52a and 52b are installed in the guide roller holders 55a and 55b. The pair of parallel wire extension position measurement units 52a and 52b, which are facing the portions of the wire electrode 1 extended in the wire guide grooves 51c of the wire parallel quide rollers 51a and 51b and running in parallel, are installed in the guide roller holders 55a and 55b.

In the guide roller holder 55a, the parallel wire extension position measurement unit 52a is disposed at a position that corresponds to a position between the pair of wire parallel guide rollers 51a and 51b and above which the cutting wire parts 1b pass. That is, in the guide roller holder 55a, the parallel wire extension position measurement unit 52a is disposed at a position closer to the workpiece W than the wire parallel guide roller 51a in the y-axis direction and below the cutting wire parts 1b.

In the guide roller holder 55b, the parallel wire extension position measurement unit 52b is disposed at a position that corresponds to a position between the pair of wire parallel guide rollers 51a and 51b and above which the cutting wire parts 1b pass. That is, in the quide roller holder 55b, the parallel wire extension position measurement unit 52b is disposed at a position closer to the workpiece W than the wire parallel guide roller 51b in the y-axis direction and below the cutting wire parts 1b.

The cutting wire parts 1b pass above the guide roller holders 55a and 55b. In the height direction, a distance between the upper surface of each of the guide roller holders 55a and 55b and the cutting wire parts 1b is set to 1 mm or less. Therefore, the installation is made so that end surfaces of sensors of the parallel wire extension position measurement units 52a and 52b installed in the guide roller holders 55a and 55b have substantially the same height as the upper surfaces of the quide roller holders 55a and 55b. The end surfaces of the sensors of the parallel wire extension position measurement units 52a and 52b are the upper surfaces of the parallel wire extension position measurement units 52a and 52b. In the example illustrated in FIG. 3, the installation is made so that an upper surface 52al which is the end surface of the sensor of the parallel wire extension position measurement unit 52a has substantially the same height as the upper surface 55al of the guide roller holder 55a.

Note that regarding the installation positions of the parallel wire extension position measurement units 52a and 52b in the height direction, the distance to the upper surface of each of the guide roller holders 55a and 55b is not always necessary to be set to 1 mm or less as long as the distance causes no interference with the cutting wire parts 1b and is within a detection capability range of the sensors of the parallel wire extension position measurement units 52a and 52b.

The pair of parallel wire extension position measurement units 52a and 52b measure a distance L to the parallel wire parts 1a facing the parallel wire extension position measurement units 52a and 52b in the height direction in a predetermined cycle during cutting, and monitor a change in the distance L. The distance L to the parallel wire parts 1a facing the parallel wire extension position measurement units 52a and 52b in the height direction can be rephrased as the distance L between the upper surfaces 55al of the guide roller holders 55a and 55b, which are predetermined measurement reference surfaces, and the parallel wire parts 1a in the height direction. That is, each of the pair of parallel wire extension position measurement units 52a and 52b measures, during cutting, the distance L between the upper surfaces 55al of the guide roller holders 55a and 55b, which are predetermined measurement reference surfaces, and the parallel wire parts 1a in the height direction.

Regarding the pair of parallel wire extension position measurement units 52a and 52b, the upper surfaces 55al of the guide roller holders 55a and 55b substantially parallel to a same virtual plane including the portions of the wire electrode 1 of the cutting wire parts 1b disposed in parallel between the pair of wire parallel guide rollers 51a and 51b are set as predetermined measurement reference surfaces, and a height position of the upper surface 52al of the parallel wire extension position measurement unit 52a which is a distal end portion of each detection unit of the parallel wire extension position measurement units 52a and 52b is set in line with the height of the measurement reference surfaces. The distal end portion of each detection unit of the parallel wire extension position measurement units 52a and 52b is the end surface of each Sensor of the parallel wire extension position measurement unit 52a.

Therefore, the pair of parallel wire extension position measurement units 52a and 52b measure the distance L between the distal end portions of the detection units of the pair of parallel wire extension position measurement units 52a and 52b and the parallel wire parts 1a in the height direction in the predetermined cycle. The pair of parallel wire extension position measurement units 52a and 52b measure the distance L between the measurement reference surfaces set parallel to a virtual plane including the plurality of cutting wire parts 1b and the portions of the wire electrode 1 constituting the plurality of cutting wire parts 1b. The pair of parallel wire extension position measurement units 52a and 52b each transmit information on the distance L which is a measurement result to the wire guide groove detachment detection unit 53.

The pair of parallel wire extension position measurement units 52a and 52b include, as a sensor, at least one of an eddy current type displacement sensor, a capacitive displacement sensor, a conduction-sensitive sensor, or a touch-sensitive displacement sensor, and measure the distance L by the sensor.

The wire guide groove detachment detection unit 53 detects the occurrence of a change exceeding a predetermined reference in the distance L detected by each of the parallel wire extension position measurement units 52a and 52b, on the basis of the measurement result obtained by each of the parallel wire extension position measurement units 52a and 52b. That is, the wire guide groove detachment detection unit 53 acquires the measurement result of the distance L between the parallel wire extension position measurement units 52a and 52b and the parallel wire parts 1a in the height direction. Then, the wire guide groove detachment detection unit 53 compares the acquired measurement result of the distance L with a distance threshold which is a predetermined reference, thereby detecting the occurrence of a change in the distance L in which the distance L exceeds the distance threshold. That is, the wire guide groove detachment detection unit 53 detects the occurrence of a change in which the distance L exceeds a predetermined reference.

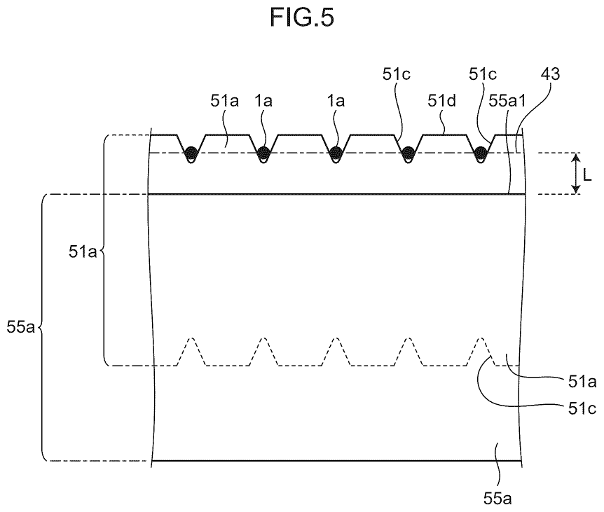

FIG. 5 is a diagram illustrating a positional relationship among the wire parallel guide roller 51a, the parallel wire parts 1a , and the quide roller holder 55a in the wire electrical discharge machining apparatus 1000 according to the first embodiment. FIG. 5 illustrates a positional relationship between the guide roller holder 55a and longitudinal cross sections of the wire parallel guide roller 51a and the parallel wire parts 1a taken along line V-V in FIG. 3. That is, FIG. 5 illustrates a positional relationship between the guide roller holder 55a and a longitudinal cross section passing through the rotation shaft 51a2 of the wire parallel guide roller 51a when the parallel wire parts 1a extended between the wire parallel guide rollers 51a and 51b and the wire parallel guide roller 51a are viewed from a direction of an arrow 103 in FIG. 3. FIG. 5 illustrates a state where the parallel wire parts 1a are hooked on the plurality of wire guide grooves 51c in the wire parallel guide roller 51a and the parallel wire parts 1a are fitted in the plurality of wire guide grooves 51c in the wire parallel quide roller 51a. FIG. 5 also illustrates a plane 43 which is a same virtual plane including the portions of the wire electrode 1 of the parallel wire parts 1a disposed in parallel between the pair of wire parallel quide rollers 51a and 51b described above.

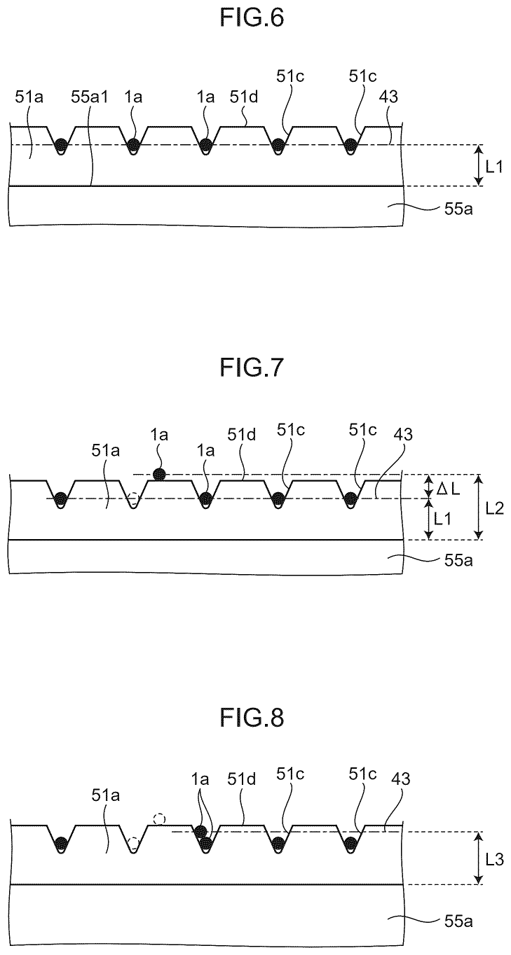

FIG. 6 is a schematic diagram illustrating the parallel wire parts 1a extended in a plurality of wire guide grooves 51c in the wire parallel guide rollers 51a and 51b included in the wire electrical discharge machining apparatus 1000 according to the first embodiment. FIG. 6 is a diagram corresponding to a part of FIG. 5. FIG. 6 illustrates a normal state where the parallel wire parts 1a are fitted in deepest portions of the wire guide grooves 51c.

FIG. 7 is a first schematic diagram illustrating an example of a state where the parallel wire part 1a is detached from the wire guide groove 51c in the wire parallel guide rollers 51a and 51b included in the wire electrical discharge machining apparatus 1000 according to the first embodiment. FIG. 7 illustrates an anomalous state where a part of the parallel wire parts 1a is detached from the wire guide groove 51c in the wire parallel guide roller 51a due to the above-described disturbance and rides on an outer peripheral surface 51d of the wire parallel guide roller 51a.

FIG. 8 is a second schematic diagram illustrating an example of the state where the parallel wire part 1a is detached from the wire guide groove 51c in the wire parallel guide roller 51a included in the wire electrical discharge machining apparatus 1000 according to the first embodiment. FIG. 8 illustrates a state where the parallel wire part 1a detached from the wire guide groove 51c in the state illustrated in FIG. 7 further moves, and the parallel wire part 1a is fitted in the adjacent wire guide groove 51c.

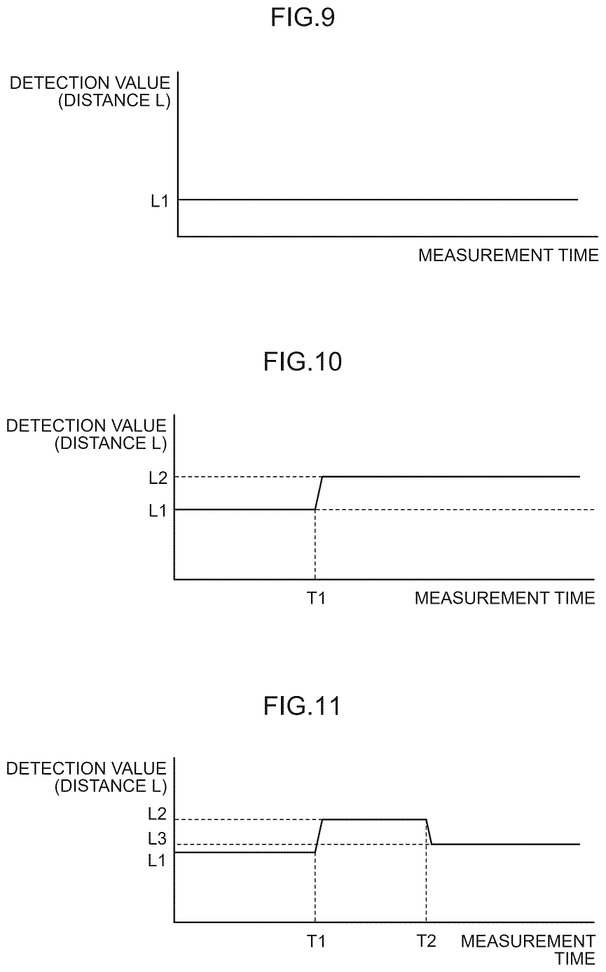

FIG. 9 is a diagram illustrating an example of a detection value of the wire guide groove detachment detection unit 53 in the state illustrated in FIG. 6. FIG. 10 is a diagram illustrating an example of a detection value of the wire quide groove detachment detection unit 53 in the state illustrated in FIG. 7. FIG. 11 is a diagram illustrating an example of a detection value of the wire guide groove detachment detection unit 53 in the state illustrated in FIG. 8. FIGS. 9 to 11 correspond to extension states of the parallel wire parts 1a , and illustrate, in graphs, detection values of the distance L between the parallel wire parts 1a facing the parallel wire extension position measurement units 52a and 52b and the parallel wire extension position measurement units 52a and 52b in the height direction, which are converted into electrical signals. The horizontal axis in each of FIGS. 9 to 11 represents measurement time. The vertical axis in each of FIGS. 9 to 11 represents detection value of distance L converted into electrical signal.

The distance L between the detection units of the parallel wire extension position measurement units 52a and 52b and the parallel wire parts 1a that the detection units face, the distance L being measured by the parallel wire extension position measurement units 52a and 52b, is determined by the position of the wire guide grooves 51c in the height direction, and does not greatly vary in a state where the electrical discharge machining is stable. However, as illustrated in FIGS. 7 and 8, an anomaly may occur in an alignment state of the parallel wire parts 1a due to a disturbance such as a change in a machining fluid flow accompanying a change in machining conditions or a fluctuation in wire tension due to an increase in electrical discharge energy.

That is, during cutting in the wire electrical discharge machining apparatus 1000, the machining fluid is ejected from the nozzles 7a and 7b toward the machining grooves along the extending direction of the parallel wire parts 1a. In a case where the workpiece W in a columnar shape is cut, the flow rate of the machining fluid is adjusted correspondingly to a cutting thickness. However, adjustment of the flow rate of the machining fluid is a factor in vibration applied to the parallel wire parts 1a and a factor in tension fluctuations of the parallel wire parts 1a. In addition, when electrical discharge energy is increased in order to speed up the electrical discharge machining, a repulsive force due to electrical discharge increases. The increase in the repulsive force due to electrical discharge is similarly a factor in the vibration applied to the parallel wire parts 1a and a factor in the tension fluctuations of the parallel wire parts 1a. Alternatively, foreign matter such as a machining debris generated during cutting is interposed in any of the wire guide grooves 51c of the wire parallel guide rollers 51a and 51b, resulting that the corresponding part of the parallel wire part 1a is locally in a shallow state due to the foreign matter in the wire guide groove 51c.

During cutting in the wire electrical discharge machining apparatus 1000, the parallel wire parts 1a are pushed out in a direction opposite to a direction of the machined surface of the workpiece W and bent by the impact force of electrical discharge. The direction of the machined surface of the workpiece W is a machining progression direction of the workpiece W by the parallel wire parts 1a. The direction opposite to the direction of the machined surface of the workpiece W can be said to be an anti-machining progression direction. That is, the parallel wire parts 1a are pushed out in the anti-machining progression direction and bent by the impact force of electrical discharge during cutting. The impact force of electrical discharge that pushes out the parallel wire parts 1a in the anti-machining progression direction during cutting is referred to as an electrical discharge repulsive force.

During cutting in the wire electrical discharge machining apparatus 1000, the parallel wire part 1a is pressed against not the deepest portions of the wire guide grooves 51c of the wire parallel quide rollers 51a and 51b but inclined surfaces on one side of the wire guide grooves 51c in a V-groove shape due to the disturbance described above, and furthermore, the parallel wire part 1a is detached from the wire guide grooves 51c and rides on the outer peripheral surfaces 51d of the wire parallel guide rollers 51a and 51b at portions between the wire guide grooves 51c and the wire guide grooves 51c adjacent thereto, and in that state, the parallel wire part 1a continues running. As a result, when the electrical discharge machining by the parallel wire parts 1a progresses, there occurs a region where the plate thickness rapidly changes in the thin plates machined thereafter, and thus it is not possible to perform collective cutting of thin plates having uniform plate thickness.

It can be seen from FIG. 9 that the distance L remains constant at a distance L1, and the parallel wire part 1a is in a normal state of being fitted in the deepest portion of the wire guide groove 51c. It can be seen from FIG. 10 that the distance L has started to change into a distance L2 from time T1, the parallel wire part 1a has started to be detached from the wire guide grooves 51c of the wire parallel guide rollers 51a and 51b, and has ridden on the outer peripheral surface 51d of the wire parallel guide roller 51a. In addition, it can be seen from FIG. 11 that the distance L2 has started to change into a distance L3 from time T2, the parallel wire part 1a detached from the wire guide groove 51c has further moved, and the parallel wire part 1a has been fitted in the adjacent wire guide groove 51c.

That is, in the wire extension state of the parallel wire parts 1a illustrated in FIG. 6, the portions of the wire electrode 1 are all extended while being fitted in the wire quide grooves 51c. Therefore, as a detection value of the distance L obtained by each of the parallel wire extension position measurement units 52a and 52b, the distance L1 having a constant value as illustrated in FIG. 9 is detected.

In FIG. 7, a portion of the wire electrode 1 of the parallel wire part 1a is detached from a part of the wire guide grooves 51c among the plurality of wire guide grooves 51c, and thereby the detection value of each of the parallel wire extension position measurement units 52a and 52b, i.e., the distance L, changes from the distance L1 in a steady state into the distance L2 as illustrated in FIG. 10, and the wire guide groove detachment detection unit 53 detects that an anomaly has occurred in the wire extension state of the parallel wire parts 1a.

In FIG. 8, the portion of the wire electrode 1 of the parallel wire part 1a detached from the wire guide groove 51c is fitted in the adjacent wire guide groove 51c, and thereby regarding the detection value of each of the parallel wire extension position measurement units 52a and 52b, the distance L changes from the distance L2 to the distance L3 as illustrated in FIG. 11, and the wire guide groove detachment detection unit 53 detects that the wire extension state of the parallel wire parts 1a has changed.

As described above, during cutting, the parallel wire extension position measurement units 52a and 52b detect a change in the distance L indicating the extension position of the parallel wire parts 1a in the height direction to be monitored. Then, the parallel wire extension position measurement units 52a and 52b send information on the detection values of the distance L which are measurement results to the wire guide groove detachment detection unit 53. The wire guide groove detachment detection unit 53 converts the detection values of the parallel wire extension position measurement units 52a and 52b into electrical signals, and calculates a change in the distance L as a difference ΔL. In the example in FIG. 7, the change from the distance LI to the distance L2 is calculated as the difference ΔL.

In a case where the difference ΔL exceeds a predetermined reference, the wire quide groove detachment detection unit 53 transmits information on the difference ΔL to the wire state determination unit 54, thereby notifying the wire state determination unit 54 of the occurrence of a change in the distance L exceeding the predetermined reference. The predetermined reference is stored in the wire guide groove detachment detection unit 53.

The wire state determination unit 54 determines whether it is a wire detachment state where at least one parallel wire part 1a is detached from the wire guide groove 51c or a wire contact state where all the parallel wire parts 1a are in contact with the wire guide grooves 51c, on the basis of the detection result obtained by the wire guide groove detachment detection unit 53. The wire state determination unit 54 determines whether there is a change in the extension state of the parallel wire parts 1a by comparing the difference ΔL transmitted from the wire guide groove detachment detection unit 53 with a predetermined determination reference value of the distance L. In a case where the difference ΔL exceeds the predetermined determination reference value of the distance L, the wire state determination unit 54 determines that there is a change in the extension state of the parallel wire parts 1a, that is, the extension state of the cutting wire parts 1b. That case corresponds to a time when an anomalous parallelness of the portions of the wire electrode 1 occurs. In a case where the difference ΔL does not exceed the predetermined determination reference value of the distance L, the wire state determination unit 54 determines that there is no change in the extension state of the parallel wire parts 1a, that is, the extension state of the cutting wire parts 1b.

The wire state determination unit 54 transmits parallel wire extension state information ps which is a determination result and state monitoring information to the machining control device 31 of the control unit 300.

The control unit 300 controls the entirety of the wire electrical discharge machining apparatus 1000. The control unit 300 controls the entirety of the wire electrical discharge machining apparatus 1000 on the basis of the state monitoring information transmitted from the wire state determination unit 54 of the wire extension state monitoring unit 400. The control unit 300 includes the machining control device 31, an electrical discharge waveform control device 32, a cutting stage drive control device 34, and a wire running control device 35.

The machining control device 31 controls the electrical discharge waveform control device 32, the cutting stage drive control device 34, and the wire running control device 35 on the basis of the parallel wire extension state information ps acquired from the wire state determination unit 54 of the wire extension state monitoring unit 400.

The electrical discharge waveform control device 32 controls the machining power supply 5 on the basis of an electrical discharge waveform command wc input from the machining control device 31, and controls a waveform of a voltage applied between the electrodes or a waveform of a current flowing between the electrodes.

The wire running control device 35 drives and controls the bobbin rotation control devices 8a and 8b on the basis of a wire electrode running command rc input from the machining control device 31, and controls the running of the wire electrode 1. In addition, the wire running control device 35 drives and controls the traverse control devices 9a and 9b on the basis of the wire electrode running command rc input from the machining control device 31, and controls traverse control.

The cutting stage drive control device 34 drives the cutting feed stage 10 on the basis of a stage command sc input from the machining control device 31, and controls the relative positions of the workpiece W and the cutting wire parts 1b.

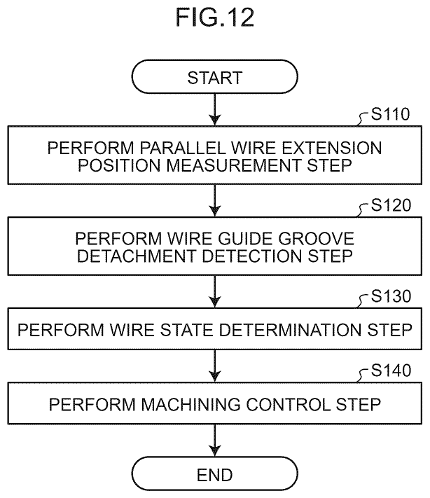

FIG. 12 is a flowchart illustrating an operation of the wire electrical discharge machining apparatus 1000 according to the first embodiment during cutting.

When the cutting is started, a parallel wire extension position measurement step is performed in step S110. That is, the parallel wire extension position measurement units 52a and 52b measure the distance L between the measurement reference surface set parallel to the virtual plane including the plurality of cutting wire parts 1b and the portions of the wire electrode 1 constituting the plurality of cutting wire parts 1b as described above. The parallel wire extension position measurement units 52a and 52b transmit information on the distance L which is a measurement result to the wire guide groove detachment detection unit 53.

Next, in step S120, a wire guide groove detachment detection step is performed. That is, the wire guide groove detachment detection unit 53 detects the occurrence of the change in the distance L on the basis of the measurement results obtained by the parallel wire extension position measurement units 52a and 52b as described above. The wire guide groove detachment detection unit 53 calculates the change in the distance L as the difference ΔL. In a case where the difference ΔL exceeds the predetermined reference, the wire guide groove detachment detection unit 53 transmits information on the difference ΔL to the wire state determination unit 54.

Next, in step S130, a wire state determination step is performed. That is, the wire state determination unit 54 determines whether it is a wire detachment state where at least one portion of the wire electrode 1 of the parallel wire part 1a is detached from the wire guide groove 51c or a wire contact state where all the portions of the wire electrode 1 of the parallel wire parts 1a are in contact with the wire guide grooves 51c, on the basis of the detection result obtained by the wire guide groove detachment detection unit 53. In a case of determining that there is a change in the extension state of the parallel wire parts 1a, the wire state determination unit 54 transmits the parallel wire extension state information ps which is state monitoring information to the machining control device 31 of the control unit 300.

Next, in step S140, a machining control step is performed. That is, the machining control device 31 controls the stop or continuation of the electrical discharge machining on the basis of the parallel wire extension state information ps which is the determination result obtained by the wire state determination unit 54. The machining control device 31 controls the continuation of the electrical discharge machining in a case where the parallel wire extension state information ps is information indicating that there is no change in the extension state of the parallel wire parts 1a, that is, the extension state of the cutting wire parts 1b. The machining control device 31 controls the stop of the electrical discharge machining in a case where the parallel wire extension state information ps is information indicating that there is a change in the extension state of the parallel wire parts 1a, that is, the extension state of the cutting wire parts 1b. That is, the machining control device 31 stops the wire electrical discharge machining simultaneously with the occurrence of the anomalous parallelness of the portions of the wire electrode 1.

As described above, the wire electrical discharge machining apparatus 1000 according to the first embodiment can detect an anomalous parallelness state caused by the portion of the wire electrode 1 of the parallel wire part 1a being detached from the wire guide groove 51c immediately after the occurrence of the anomalous parallelness state. The anomalous parallelness state is an anomaly in which the plurality of portions of the wire electrode 1 of the cutting wire parts 1b originally extended between the pair of wire parallel guide rollers 51a and 51b in parallel and at equal intervals are not extended in parallel and at equal intervals. That is, the wire electrical discharge machining apparatus 1000 can detect positional displacement of the wire electrode 1 accurately and at an early stage, and can detect a defect caused by the positional displacement of the wire electrode 1 accurately and at an early stage. The wire electrical discharge machining apparatus 1000 can detect the anomalous parallelness state due to the detachment of a part of the portions of the wire electrode 1 of the parallel wire parts 1a from the wire guide groove 51c immediately after the occurrence of the anomalous parallelness state, and the wire electrical discharge machining is stopped simultaneously with the occurrence of the anomalous parallelness of the portion of the wire electrode 1. Therefore, it is possible to prevent a large amount of thin plates from being machined, the plate thickness of which is varied in the middle of machining, by the electrical discharge machining in which the distance between the portions of the wire electrode 1 of the parallel wire parts 1a disposed in parallel has changed in the middle of cutting.

In addition, since the wire electrical discharge machining apparatus 1000 stops the cutting simultaneously with the occurrence of the anomalous parallelness of the portions of the wire electrode 1, anomalous portions formed on surfaces of the thin plates being cut can be minimized. Consequently, after a parallel state of the parallel wire parts 1a is repaired, the wire electrical discharge machining apparatus 1000 can resume the cutting from a machining stop position with no machining instability, and can improve the machining accuracy of the thin plates and improve the yield of thin plate machining. Therefore, the wire electrical discharge machining apparatus 1000 does not waste expensive semiconductor crystals when cutting a semiconductor ingot, for example, and thus can reduce a Wafer production cost.

Moreover, since the wire electrical discharge machining apparatus 1000 can stop, at an early stage, the cutting in the anomalous parallelness state of the parallel wire parts 1a, it is possible to prevent formation of a meandering portion of the machined groove of the workpiece W, which causes a decrease in the amount of the machining fluid supplied between the electrodes and a hindrance to discharge of machining debris during the cutting, and to prevent disconnection of the wire electrode 1.

Furthermore, in the wire electrical discharge machining apparatus 1000, the parallel wire extension position measurement units 52a and 52b include, as a sensor, at least one of an eddy current type displacement sensor, a capacitive displacement sensor, a conduction-sensitive sensor, and a touch-sensitive displacement sensor, and measure the distance L by the sensor. Consequently, the wire electrical discharge machining apparatus 1000 can detect an anomalous parallelness state caused by a part of the portions of the wire electrode 1 of the parallel wire parts 1a being detached from the wire guide groove 51c immediately after the occurrence of the anomalous parallelness state, accurately and at an early stage.

Therefore, the wire electrical discharge machining apparatus 1000 according to the first embodiment achieves an effect that it is possible to provide the wire electrical discharge machining apparatus 1000 capable of accurately detecting a defect caused by positional displacement of the wire electrode 1. The wire electrical discharge machining apparatus 1000 achieves an effect that it is possible to make the plate thickness of the thin plates to be collectively cut from the workpiece W uniform.

### Second Embodiment

In a second embodiment, another function of the wire electrical discharge machining apparatus 1000 will be described. The wire electrical discharge machining apparatus 1000 that collectively cuts thin plates by the cutting wire parts 1b individually supplies machining power from the machining power supply 5 to each of the portions of the wire electrode 1 of the parallel wire parts 1a running in parallel at a predetermined interval. The machining power is supplied to each of the portions of the wire electrode 1 of the parallel wire parts 1a in a pulsed manner, and is supplied only during a predetermined power supply time or voltage application time.

For example, between a voltage and a voltage applied in a pulsed manner, a pause time during which no voltage is applied is set at a predetermined time interval. In addition, in order to cope with a high-frequency pulse oscillation command for supplying the machining power to the portions of the wire electrode 1 of the parallel wire parts 1a, the machining power supply 5 uses a system in which a plurality of power supply devices are combined to enable a power-on operation and a power-off operation to be performed in a short time. In such a machining power supply 5, depending on a timing of switching from an off state where the machining power is not applied to each of the portions of the wire electrode 1 of the parallel wire parts 1a to an on state where the machining power is applied to each of the portions of the wire electrode 1 of the parallel wire parts 1a, the power supply devices may be damaged by arm short-circuit in which power is simultaneously turned on in the power supply devices.

In the wire electrical discharge machining apparatus 1000, in order to avoid a possibility of such damage of the power supply devices, a time called a dead time is also set during which voltage application to all the combined power supply devices is stopped, in addition to an off time during which power is not applied to the portions of the wire electrode 1 of the parallel wire parts 1a. The pulsed power supply as described above from the machining power supply 5 to each power feed contact 11 or the power feed contact units 6a and 6b is controlled by the machining control device 31 and the electrical discharge waveform control device 32.

In the wire electrical discharge machining apparatus 1000, during cutting, a voltage is applied in a pulsed manner between each of the portions of the wire electrode 1 of the parallel wire parts 1a and the workpiece W via the power feed contacts 11 connected to the machining power supply 5 by power supply lines 12a and 12b, and thus electrical discharge is generated. An electrical discharge waveform of the electrical discharge generated between the electrodes, i.e., between the portions of the wire electrode 1 of the cutting wire parts 1b and the workpiece W varies correspondingly to a distance between the electrodes, i.e., between the portions of the wire electrode 1 of the cutting wire parts 1b and the workpiece W at a time of machining power application.

In a state where the portions of the wire electrode 1 of the cutting wire parts 1b and the workpiece W at the time of machining power application are relatively separated from each other, that is, in a state where an inter-electrode distance between the portions of the wire electrode 1 of the cutting wire parts 1b and the workpiece W at the time of machining power application is relatively long, an electrical discharge waveform with a relatively low peak is obtained. In a state where the portions of the wire electrode 1 of the cutting wire parts 1b and the workpiece W at the time of machining power application are relatively close to each other, that is, in a state where the inter-electrode distance between the portions of the wire electrode 1 of the cutting wire parts 1b and the workpiece W at the time of machining power application is relatively short, an electrical discharge waveform with a relatively high peak is obtained. In a state where the inter-electrode distance between the portions of the wire electrode 1 of the cutting wire parts 1b and the workpiece W at the time of machining power application is an appropriate inter-electrode distance, an electrical discharge waveform with an intermediate peak between that in an open state and that in a short-circuit state is obtained.

Here, the “open state” and the “short-circuit state” will be described. When the machining power is applied in a pulsed manner between the cutting wire parts 1b and the workpiece W, the magnitude of an electrical discharge pulse to be generated changes correspondingly to the distance between the cutting wire parts 1b and the workpiece W, that is, correspondingly to the inter-electrode distance. If the inter-electrode distance, which is a distance between the electrodes which is a gap between the cutting wire parts 1b and the workpiece W, is large, electrical discharge is less likely to occur between the electrodes, and if no electrical discharge occurs, no electrical discharge current flows. Such a state where no electrical discharge occurs between the electrodes and no electrical discharge current flows therebetween is defined as the “open state”.

In the open state, an electrical discharge voltage waveform during a pulse application time substantially maintains the level of the voltage that has been applied, and an electrical discharge current waveform has a low value. However, depending on the specific resistance of deionized water used as the machining fluid, that is, the specific conductivity of the deionized water, and the magnitude of insulation resistance between the power feed contacts 11 adjacent to each other, the electrical discharge current may be detected as some leakage current.

On the other hand, when the cutting wire parts 1b extremely approach the workpiece W or the cutting wire parts 1b come into contact with the workpiece W, electrical discharge is generated between the electrodes substantially simultaneously with pulse application, and a large electrical discharge current flows due to small insulation resistance between the electrodes. Such a state is defined as the “short-circuit state”.

In the wire electrical discharge machining apparatus 1000 that adopts a method in which electrical discharge machining is performed in deionized water, the insulation between the electrodes is provided by the specific resistance of the deionized water interposed between the electrodes. However, a decrease in the inter-electrode distance results in a decrease in the specific resistance between the electrodes, so that an electrical discharge current with a small resistance loss or a current supplied from the machining power supply 5 flows between the electrodes. In that state, an electrical discharge voltage greatly decreases, and the electrical discharge current has a waveform with a high peak.

The “state where the inter-electrode distance between the wire electrode 1b and the workpiece W is an appropriate inter-electrode distance” is classified into a state where the inter-electrode distance is a distance that causes neither the short-circuit state nor the open state. Since it is difficult to directly measure the inter-electrode distance during cutting, the wire electrical discharge machining apparatus 1000 constantly monitors states of the electrical discharge waveform to appear. Then, in the wire electrical discharge machining apparatus 1000, when a tendency of shift from a state where an electrical discharge state which is not the open state nor the short-circuit state continues to occur to a state of the “open state” or the “short-circuit state” is detected in the electrical discharge waveform, a stable electrical discharge state is continued by machining control for adjusting various conditions such as an applied voltage, a machining current, an electrical discharge frequency, a voltage application pulse time, and a pulse application pause time.

The wire electrical discharge machining apparatus 1000 monitors the electrical discharge waveform as described above, estimates the state between the electrodes, i. e., between the portions of the wire electrode 1 of the cutting wire parts 1b and the workpiece W during cutting, and controls the cutting such that an electrical discharge waveform that leads to stable cutting often appears.

The machining control device 31 transmits, to the electrical discharge waveform control device 32, command information commanding the oscillation frequency of the electrical discharge pulse during the electrical discharge machining or commanding an on time and an off time of the electrical discharge pulse, and controls electrical discharge energy supplied between the electrodes, i.e., between the portions of the wire electrode 1 of the cutting wire parts 1b and the workpiece W, from the machining power supply 5. The machining control device 31 transmits command information commanding a machining feed speed to the cutting stage drive control device 34, and controls the inter-electrode distance.

In the thin plate machining by the wire electrical discharge machining apparatus 1000 as described above, there are rare occurrences of a situation in which electrical discharge machining is continued even in a state where the cutting wire parts 1b are completely in contact with the workpiece W, for example, when the workpiece W having a relatively high specific resistance such as a semiconductor wafer material is used. The situation corresponds to a case where a machining current flowing through the cutting wire parts 1b while the cutting wire parts 1b are completely in contact with the workpiece w does not satisfy a pulse oscillation condition that provides the amount of heat sufficient to fuse the wire electrode 1, a case where a short circuit between the cutting wire parts 1b and the workpiece W occurs partially in a region of the cutting wire parts 1b, but normal electrical discharge occurs between the electrodes in other portions of the cutting wire parts 1b, and thus electrical discharge cutting is continued, or the like, and is attributable to the fact that it is not possible to accurately observe or correctly determine the situation in which the short circuit continues.

As described above, when the cutting of the thin plates is continued in a state where the cutting wire parts 1b and the workpiece W are short-circuited and the cutting wire parts 1b are in contact with the workpiece W without disconnection, regarding the portions of the wire electrode 1 of the cutting wire parts 1b being in contact with the workpiece W, the cutting does not proceed beyond positions where the portions of the wire electrode 1 are short-circuited to the workpiece W. Despite such a situation, the portions of the wire electrode 1 of the cutting wire parts 1b short-circuited to the workpiece W continue to rise while being in contact with the workpiece W and being pulled up by the cutting feed stage 10 together with the workpiece W.

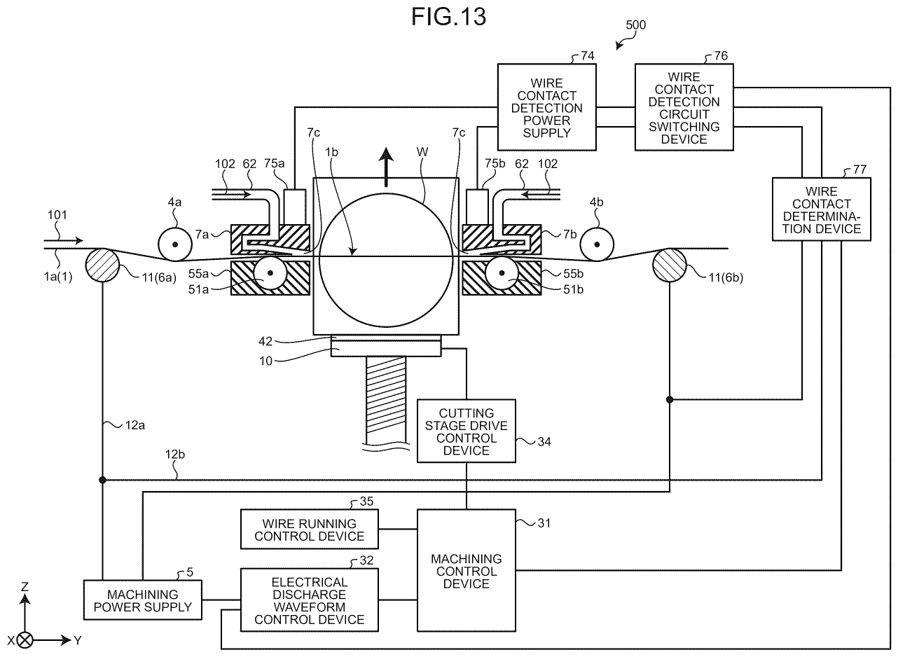

In the second embodiment, the wire electrical discharge machining apparatus 1000 includes a wire contact machining state monitoring unit 500. FIG. 13 is a schematic diagram illustrating an exemplary configuration of the wire contact machining state monitoring unit 500 of the wire electrical discharge machining apparatus 1000 in the second embodiment. FIG. 13 illustrates a state where the electrical discharge machining is performed by the cutting wire parts 1b, and the wire electrical discharge machining performed on the workpiece W in a columnar shape has proceeded to a position corresponding to about ½ of the diameter of the workpiece W, where the wire electrode 1 is in contact with the workpiece W and short-circuited. In FIG. 13, the thin plate machining stabilization unit 70 is not illustrated. In FIG. 13, an illustration of the configuration of the wire extension state monitoring unit 400 is omitted.

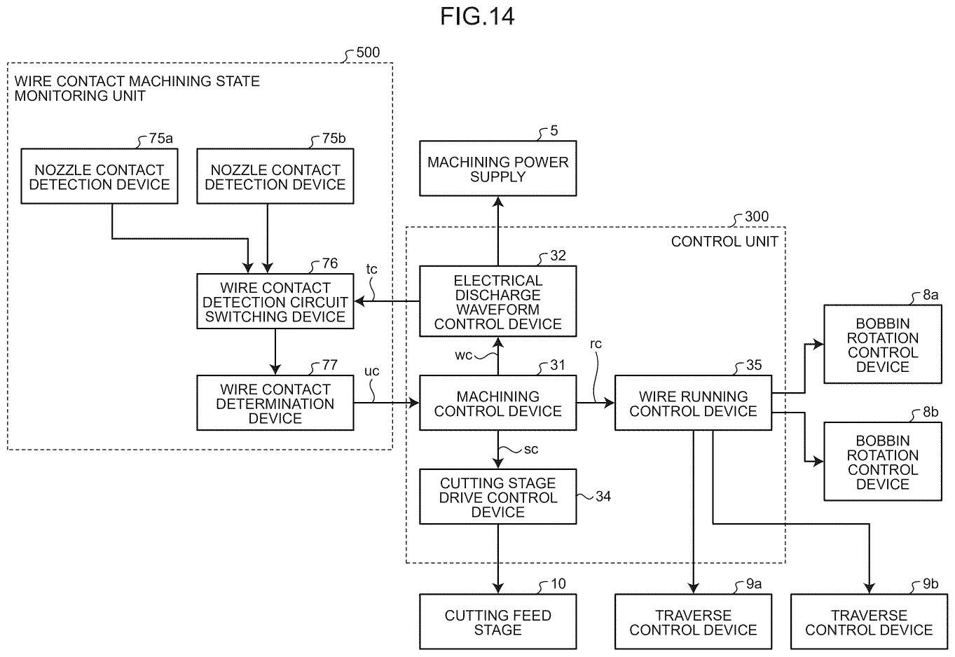

The wire contact machining state monitoring unit 500 monitors a state of contact between the parallel wire parts 1a and the nozzles 7a and 7b during cutting. FIG. 14 is a block diagram illustrating exemplary configurations of the control unit 300 and the wire contact machining state monitoring unit 500 included in the wire electrical discharge machining apparatus 1000 in the second embodiment. The wire contact machining state monitoring unit 500 includes nozzle contact detection devices 75a and 75b, a wire contact detection circuit switching device 76, and a wire contact determination device 77.

The nozzle contact detection devices 75a and 75b are connected to the wire contact detection circuit switching device 76 and the nozzles 7a and 7b. The wire contact detection circuit switching device 76 is connected to the nozzle contact detection devices 75a and 75b, the wire contact determination device 77, and the electrical discharge waveform control device 32 of the control unit 300. The wire contact determination device 77 is connected to the nozzle contact detection devices 75a and 75b, the power supply lines 12a and 12b connecting the machining power supply 5 and the power feed contacts 11, or the machining power supply 5, and the machining control device 31 of the control unit 300. The wire contact machining state monitoring unit 500 is thus configured.

The nozzle contact detection devices 75a and 75b detect characteristic values related to potential differences between the nozzles 7a and 7b and the power feed contacts 11. Specifically, the nozzle contact detection devices 75a and 75b detect a current, a voltage, or a resistance value in a wire contact detection circuit. The nozzle contact detection devices 75a and 75b transmit information on the current, the voltage, or the resistance value in the wire contact detection circuit, which is a detection result, to the wire contact determination device 77.

The wire contact detection circuit includes the nozzle contact detection devices 75a and 75b, the nozzles 7a and 7b, the cutting wire parts 1b, the power feed contacts 11, the power supply lines 12a and 12b, and the wire contact determination device 77. Power is supplied to the wire contact detection circuit from a wire contact detection power supply 74 under the control of the wire contact detection circuit switching device 76.

The wire contact detection circuit switching device 76 controls opening and closing of the wire contact detection circuit. The wire contact detection circuit switching device 76 connects the wire contact detection circuit, that is, closes the wire contact detection circuit, during a machining power off time during which no machining voltage is applied between the electrodes. In addition, the wire contact detection circuit switching device 76 disconnects the wire contact detection circuit, that is, opens the wire contact detection circuit, during a machining power on time during which the machining voltage is applied between the electrodes.

The wire contact determination device 77 monitors a change in a current value, a voltage value, or the resistance value in the wire contact detection circuit. When detecting a change in the current value, the voltage value, or the resistance value in the wire contact detection circuit, the wire contact determination device 77 determines that it is a short-circuit machining continuation state due to non-detection of contact between the portions of the wire electrode 1 of the parallel wire parts 1a and the nozzles 7a and 7b, and transmits a signal uc indicating a contact machining state to the machining control device 31.

Originally, a linear extension state of the cutting wire parts 1b extended between the pair of wire parallel guide rollers 51a and 51b is maintained in a state where the cutting wire parts 1b are spaced apart from the workpiece W between the pair of wire parallel guide rollers 51a and 51b. On the other hand, the portions of the wire electrode 1 of the cutting wire parts 1b pulled up by the cutting feed stage 10 while being in contact with the workpiece W eventually come into contact with the nozzles 7a and 7b that should not be contacted. FIG. 13 illustrates a state where the portions of the wire electrode 1 of the cutting wire parts 1b pulled up by the cutting feed stage 10 while being in contact with the workpiece W are in contact with the nozzles 7a and 7b that should not be contacted.

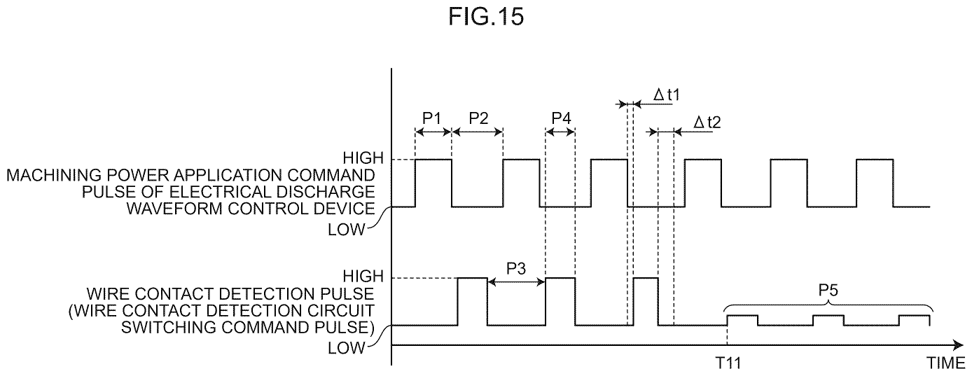

FIG. 15 is a characteristic diagram illustrating a timing of switching between machining voltage application and wire contact detection of the wire electrical discharge machining apparatus 1000 in the second embodiment. FIG. 15 illustrates waveforms of a machining power application command pulse and a wire contact detection pulse.

The machining power application command pulse is a command pulse with which the electrical discharge waveform control device 32 gives a command regarding a timing of applying the machining voltage to the machining power supply 5.

The wire contact detection pulse is a pulse power supply with which the wire contact detection power supply 74 supplies the wire contact detection circuit with detection power for detecting that contact has been made with the portions of the wire electrode 1 of the cutting wire parts 1b. The wire contact detection pulse is a pulse oscillated in a phase opposite to that of the machining power application command pulse which is a command pulse for commanding the timing of applying the machining voltage between the electrodes by the machining power supply 5. It can also be said that the wire contact detection pulse is a wire contact detection circuit switching command pulse for performing switching between opening and closing of the wire contact detection circuit.

When receiving the machining power application command pulse which is a command pulse for commanding the timing of applying the machining voltage from the electrical discharge waveform control device 32, the machining power supply 5 supplies power to each power feed contact 11 on the basis of the machining power application command pulse, and individually supplies power to each of the parallel wire parts 1a. Consequently, a voltage is applied between the electrodes, i.e., between the cutting wire parts 1b and the workpiece W.

When the machining power application command pulse from the electrical discharge waveform control device 32 is in a LOW state, a period during which the machining power application command pulse is in the LOW state is machining power off time P2. During the machining power off time P2, there occurs a machining power off state where no power is supplied from the machining power supply 5 to each power feed contact 11, and the machining voltage is not applied between the electrodes, i. e., between the cutting wire parts 1b and the workpiece W.

When the machining power application command pulse enters a HIGH state after the machining power off time P2 during which no machining voltage is applied, a period during which the machining power application command pulse is in the HIGH state is machining power application time P1. During the machining power application time P1, there occurs a machining power on state where power is supplied from the machining power supply 5 to each power feed contact 11, and the machining voltage is applied between the electrodes, i.e., between the cutting wire parts 1b and the workpiece W. In a case where electrical discharge occurs between the electrodes when the machining power application command pulse is in the HIGH state, a machining current is supplied from the machining power supply 5 to the power feed contacts 11.

While the operation of applying a voltage between the electrodes as described above is repeated, a command pulse to is sent from the electrical discharge waveform control device 32 to the wire contact detection circuit switching device 76.

The wire contact detection circuit switching device 76 connects the wire contact detection circuit in a case of the machining power off time P2 during which no machining voltage is applied between the electrodes, that is, in a case where the machining power application command pulse transmitted from the electrical discharge waveform control device 32 to the machining power supply 5 is in the LOW state. In addition, the wire contact detection circuit switching device 76 disconnects the wire contact detection circuit during the machining power on time during which the machining power application command pulse transmitted from the electrical discharge waveform control device 32 to the machining power supply 5 is in the HIGH state and the machining voltage is applied between the electrodes, that is, during the machining power application time P1.

The machining power off time P2 corresponds to a period during which the wire contact detection pulse is in the HIGH state. The period during which the wire contact detection pulse is in the LOW state is detection power off time P3 during which the detection power is not supplied to the wire contact detection circuit. The period during which the wire contact detection pulse is in the HIGH state is short-circuit detection time P4 during which the detection power is supplied to the wire contact detection circuit and the presence or absence of a short circuit between the workpiece W and the cutting wire parts 1b is detected. The period after time T11 is short-circuit machining continuation time P5 during which the cutting is performed in a state where the cutting wire parts 1b are completely short-circuited to the workpiece W.

A waveform of the short-circuit machining continuation time P5 during which the cutting is performed in a state where the cutting wire parts 1b are completely short-circuited to the workpiece W is present in the wire contact detection pulse. The wire contact detection pulse has a waveform indicating that the wire contact detection power supply 74 supplies the wire contact detection circuit with detection power for detecting that contact has been made with the portions of the wire electrode 1 of the cutting wire parts 1b.

If power for detecting a potential change corresponding to the contact state of the cutting wire parts 1b with respect to the workpiece W can be constantly applied to the wire contact detection circuit, configurations of an oscillation circuit and a detection processing system can be simplified. However, since machining power is applied to the cutting wire parts 1b and the workpiece W in addition to the detection power, two types of power, i.e., the detection power and the machining power, are supplied thereto. Therefore, it is necessary to prevent a state where two types of voltages of the detection power and the machining power are simultaneously applied to the cutting wire parts 1b and the workpiece W.

Therefore, the wire electrical discharge machining apparatus 1000 adopts a method in which a wire contact detection pulse is applied to the cutting wire parts 1b and the workpiece W in a no-load time during which a pulsed machining voltage is not applied, as a measure for preventing a state where the two types of voltages of the detection power and the machining power are simultaneously applied to the cutting wire parts 1b and the workpiece W. Since the wire contact detection circuit is not closed unless the cutting wire parts 1b are in contact with the workpiece W, the current supplied from the wire contact detection power supply 74 does not flow through the wire contact detection circuit, and voltage drop does not occur. Therefore, the voltage applied to the wire contact detection circuit is in a high state, that is, in the HIGH state.

On the other hand, when the cutting wire parts 1b come into contact with the workpiece W, the wire contact detection circuit is closed via the workpiece W being conductive. In that case, as compared with a case where there is no contact between the cutting wire parts 1b and the workpiece W, the potentials detected by the nozzle contact detection devices 75a and 75b decrease, that is, are in the LOW state.

Therefore, in the wire electrical discharge machining apparatus 1000, it is possible to determine whether the cutting wire parts 1b and the workpiece W are in contact with each other or the cutting wire parts 1b and the workpiece W are in no contact with each other, on the basis of states of voltages regarding the potentials detected by the nozzle contact detection devices 75a and 75b, for example, whether a pulsed voltage applied to the wire contact detection circuit is in the HIGH state or the LOW state as illustrated in FIG. 15.

In a normal electrical discharge machining state, the cutting wire parts 1b are not in contact with the nozzles 7a and 7b, and thus the wire contact detection circuit is open. On the other hand, as described above, in a case where contact that has been made between the cutting wire parts 1b and the workpiece W is not detected, machining feeding by the cutting stage drive control device 34 is continued, so that the cutting wire parts 1b that have been pulled up come into contact with the nozzles 7a and 7b made of metal, and thereby the wire contact detection circuit is closed.

When the wire contact detection circuit is connected by the wire contact detection circuit switching device 76, the wire contact determination device 77 detects a change in a current value, a voltage value, or a resistance value in the wire contact detection circuit. The wire contact determination device 77 detects the change in the current value, the voltage value, or the resistance value of the wire contact detection circuit by comparing the current value, the voltage value, or the resistance value in the wire contact detection circuit detected when the wire contact detection circuit is connected by the wire contact detection circuit switching device 76 with a predetermined determination reference value of the current value, the voltage value, or the resistance value.

The predetermined determination reference value of the current value, the voltage value, or the resistance value is a current value, a voltage value, or a resistance value of the wire contact detection circuit in a state where the cutting wire parts 1b that have come into contact with the workpiece W and have been pulled up are in contact with the nozzles 7a and 7b made of metal.

In a case where the current value, the voltage value, or the resistance value in the wire contact detection circuit that has been detected exceeds a determination reference value corresponding to the value, the wire contact determination device 77 determines that there is a change in the current value, the voltage value, or the resistance value, and determines that the change in the current value, the voltage value, or the resistance value of the wire contact detection circuit has been detected. In a case where the current value, the voltage value, or the resistance value in the wire contact detection circuit that has been detected does not exceed the determination reference value corresponding to the value, the wire contact determination device 77 determines that there is no change in the current value, the voltage value, or the resistance value, and determines that the change in the current value, the voltage value, or the resistance value of the wire contact detection circuit has not been detected.

When detecting the change in the current value, the voltage value, or the resistance value of the wire contact detection circuit, the wire contact determination device 77 determines that it is a short-circuit machining continuation state where cutting is being performed while the workpiece W and the cutting wire parts 1b are short-circuited, due to non-detection of contact, i.e., the fact that contact between the portions of the wire electrode 1 of the parallel wire parts 1a and the nozzles 7a and 7b is not detected. The short-circuit machining continuation state can be rephrased as a contact machining state where cutting is performed while the workpiece W and the cutting wire parts 1b are in contact with each other. Then, the wire contact determination device 77 transmits the signal uc indicating the contact machining state to the machining control device 31.

When receiving the signal uc indicating the contact machining state, the machining control device 31 commands the electrical discharge waveform control device 32 to stop oscillation of the machining power supply 5, the wire running control device 35 to stop wire running, and the cutting stage drive control device 34 to stop the cutting feed stage 10 on the basis of the signal uc. That is, the machining control device 31 controls the stop of the application of the voltage between the electrodes, the stop of the running of the wire electrode 1, and the stop of the movement of the cutting feed stage 10 and the workpiece W on the basis of the signal uc, and stops the cutting.

The wire contact detection power supply 74 applies the detection power to the wire contact detection circuit so that the detection power is not to be applied simultaneously with the machining power to be supplied between the electrodes from the machining power supply 5.

That is, the wire contact detection power supply 74 supplies wire contact power to the wire contact detection circuit with the wire contact detection pulse.

When the wire contact detection circuit is connected even for a short time in a state where the machining power is applied between the electrodes from the machining power supply 5, the machining power is connected also to the wire contact detection circuit from the power feed contacts 11 or the power supply lines 12a and 12b, and a device constituting the wire contact detection circuit may be damaged. Alternatively, when the wire contact detection circuit is connected even for a short time in a state where the machining power is applied between the electrodes, detection power for the machining power application command pulse is applied between the electrodes, and the electrical discharge machining may become unstable.

Therefore, in the wire contact detection power supply 74, not only that the oscillation is performed in a phase opposite to that of the machining power application command pulse, but also that a period is set during which neither the machining power application command pulse nor the wire contact detection pulse is in the on state, which is a period of several hundred nanoseconds denoted by Δt1 immediately after the machining power application command pulse changes from HIGH to LOW and a period of several hundred nanoseconds denoted by Δt2 immediately before the machining power application command pulse changes from LOW to HIGH, as illustrated in FIG. 15.

The machining power application command pulse sent from the electrical discharge waveform control device 32 to the machining power supply 5 is also sent to the wire contact detection circuit switching device 76. The wire contact detection circuit switching device 76 refers to the machining power application command pulse, and opens and closes the wire contact detection circuit on the basis of the timing of applying the pulsed voltage of the machining power supply 5 to the power feed contacts 11.

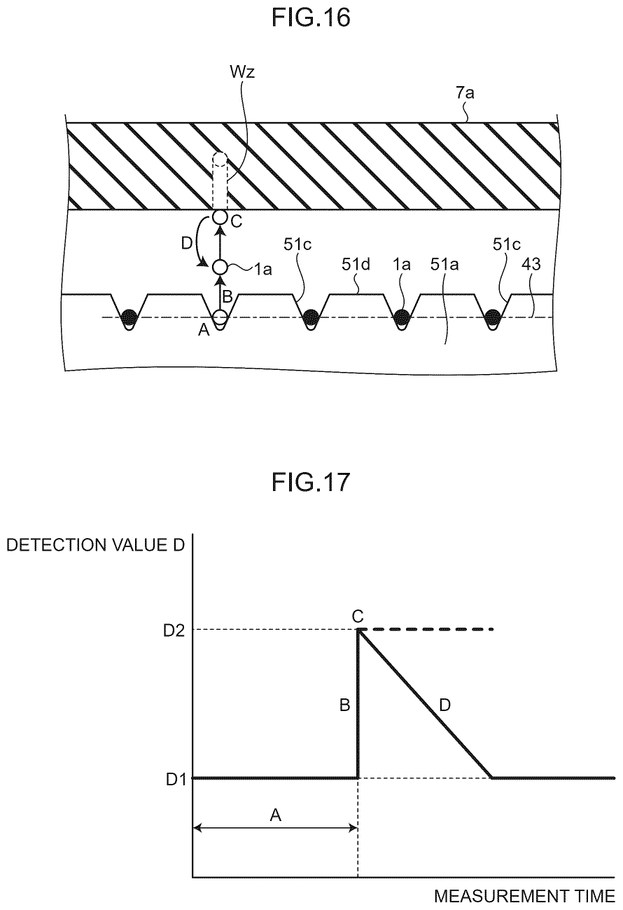

FIG. 16 is a schematic diagram illustrating an example of a state where the parallel wire part 1a is detached from the wire guide groove 51c in the wire parallel quide roller 51a of the wire electrical discharge machining apparatus 1000 in the second embodiment. FIG. 16 illustrates a longitudinal cross section passing through the rotation shaft 51a2 of the wire parallel guide roller 51a, regarding the nozzle 7a, the parallel wire parts 1a extended between the wire parallel guide rollers 51a and 51b, and the wire parallel guide roller 51a. In addition, FIG. 16 illustrates a state where the cutting is continued while a part of the portions of the wire electrode 1 of the parallel wire parts 1a is in contact with the workpiece w, consequently the parallel wire part 1a extended in the wire guide groove 51c rises and eventually comes into contact with the nozzle 7a, and the cutting is further continued to thereby cut the nozzle 7a. In FIG. 16, the parallel wire part 1a to be detached from the wire guide groove 51c is indicated by an open circle.

FIG. 17 is a conceptual diagram illustrating a detection value corresponding to the wire detachment state in FIG. 16 and determination of a state corresponding to the detection value. A detection value D is a current value, a voltage value, or a resistance value in the wire contact detection circuit when the wire contact detection circuit is connected by the wire contact detection circuit switching device 76. FIG. 17 schematically illustrates a monitored situation regarding the behavior of the parallel wire part 1a detached from the wire guide groove 51c in FIG. 16 by a detection value in the wire contact machining state monitoring unit 500 of the wire electrical discharge machining apparatus 1000.

In FIG. 16, in the steady state, the parallel wire parts 1a fit into the deepest portions of the wire guide grooves 51c and normal cutting is performed (state A). Thereafter, there occurs a situation in which a part of the portions of the wire electrode 1 of the parallel wire parts 1a is short-circuited to a machined surface of the workpiece W, and the cutting is continued in a state where the part of the portions of the wire electrode 1 of the parallel wire parts 1a is in contact with the machined surface of the workpiece W without disconnection. Consequently, with the machining feeding by the cutting feed stage 10 of the workpiece W in contact with the part of the portions of the wire electrode 1 of the parallel wire parts 1a, the portion of the wire electrode 1 enters an anomalous extension state where the portion of the wire electrode 1 starts to rise from the wire guide groove 51c (state B). Then, when the cutting is continued without eliminating the anomalous extension state, the portion of the wire electrode 1 that has risen eventually comes into contact with the nozzle 7a (state C). When the cutting is further continued, the portion of the wire electrode 1 that has come into contact with the nozzle 7a runs to thereby rub and cut the nozzle 7a, and a cut groove Wz is formed in the nozzle 7a. In a case where the state C is continued, disconnection of the wire electrode 1 occurs.

A phenomenon similar to that described above occurs in the nozzle 7b, the parallel wire parts 1a extended between the wire parallel guide rollers 51a and 51b, and the wire parallel guide roller 51b.

In FIG. 17, the state A which is a steady state where there is no anomaly in the wire extension state transitions into the state B where the portion of the wire electrode 1 is in contact with the nozzle 7a, through the state B. At that time, in the wire contact machining state monitoring unit 500, the detection value D changes from a detection value Dl in the steady state to a detection value D2, and thereby the wire contact determination device 77 detects the occurrence of the state C which is the wire contact state with respect to the nozzle 7a. The wire contact determination device 77 detects the occurrence of the state C on the basis of the detection value obtained by the nozzle contact detection device 75a when the wire contact detection circuit is connected by the wire contact detection circuit switching device 76.

The wire contact determination device 77 transmits the signal uc indicating the contact machining state to the machining control device 31. The machining control device 31 commands the electrical discharge waveform control device 32 to stop oscillation of the machining power supply 5, the wire running control device 35 to stop wire running, and the cutting stage drive control device 34 to stop the cutting feed stage 10 on the basis of the signal uc. Alternatively, when receiving the signal uc indicating the contact machining state from the wire contact determination device 77, the machining control device 31 commands the electrical discharge waveform control device 32 to temporarily stop the oscillation of the machining power supply 5 or to perform oscillation frequency control to rapidly decrease the oscillation frequency of the machining power supply 5, or commands the wire running control device 35 to reverse the feeding direction of the wire electrode 1 by the cutting stage drive control device 34 from the cutting progression direction and to rapidly retreat the cutting feed stage 10 (state D in FIGS. 16 and 17). That is, the machining control device 31 controls a retreat operation for eliminating short circuit in which the feeding direction of the cutting stage drive control device 34 is reversed from the cutting progression direction, on the basis of the signal uc. Consequently, the wire electrical discharge machining apparatus 1000 can return, into the wire guide groove 51c without interrupting the cutting, the portion of the wire electrode 1 that has been anomalously extended.

In addition, in a case where the retreat operation for eliminating short circuit is not performed on the basis of the signal uc, the machining control device 31 stops power supply to all the parallel wire parts 1a and stops the cutting. Consequently, the machining control device 31 can stop the cutting simultaneously with the occurrence of the anomalous parallelness of the portions of the wire electrode 1.

As described above, according to the second embodiment, it is possible to detect that a part of the portions of the wire electrode 1 of the parallel wire parts 1a is detached from the wire guide groove 51c and is in contact with the nozzles 7a and 7b, and to stop the cutting when the portion of the wire electrode 1 comes into contact with the nozzles 7a and 7b. Consequently, according to the second embodiment, it is possible to prevent peripheral devices constituting the wire electrical discharge machining apparatus 1000 such as the nozzles 7a and 7b from being damaged due to friction with the wire electrode 1.

According to the second embodiment, when the portion of the wire electrode 1 detached from the wire guide groove 51c comes into contact with the nozzles 7a and 7b, disconnection of the wire electrode 1 is prevented by control of oscillation of the machining power supply 5. That is, the wire electrical discharge machining apparatus 1000 performs control to temporarily stop oscillation of the machining power supply 5 or oscillation frequency control to rapidly decrease the oscillation frequency of the machining power supply 5 when the portion of the wire electrode 1 detached from the wire guide groove 51c comes into contact with the nozzles 7a and 7b, thereby preventing disconnection of the wire electrode 1 caused by the cutting continued in the contact machining state.

According to the second embodiment, when the portion of the wire electrode 1 detached from the wire guide groove 51c comes into contact with the nozzles 7a and 7b, the portion of the wire electrode 1 is retreated from the wire contact state by the drive control of the cutting feed stage 10. Therefore, the portion of the wire electrode 1 that has been anomalously extended can be returned into the wire guide groove 51c without interrupting the cutting.

According to the second embodiment, since the wire electrical discharge machining apparatus 1000 stops the cutting simultaneously with the occurrence of the anomalous parallelness of the portions of the wire electrode 1, machining performed while the portion of the wire electrode 1 is in contact can be minimized, and anomalous portions formed on the surfaces of the thin plates being cut can be minimized. Consequently, the wire electrical discharge machining apparatus 1000 can resume machining after restoring the extension state of the portions of the wire electrode 1 in the anomalous extension state and power supply to the wire electrode 1, can resume cutting from the machining stop position with no machining instability, can improve the machining accuracy of the thin plates and improve the yield of thin plate machining. Therefore, the wire electrical discharge machining apparatus 1000 does not waste expensive semiconductor crystals when cutting a semiconductor ingot, for example, and thus can reduce a wafer production cost.

According to the second embodiment, cutting of the workpiece W due to friction of the portion of the wire electrode 1 that has come into contact with the workpiece W is prevented, so that it is possible to prevent formation of a meandering portion of the machined groove of the workpiece W, which causes a decrease in the amount of the machining fluid supplied between the electrodes and a hindrance to discharge of machining debris during the cutting, and to prevent disconnection of the wire.

Consequently, the wire electrical discharge machining apparatus 1000 does not waste expensive semiconductor crystals when cutting a semiconductor ingot, for example, can improve the yield of thin plate machining, and thus can reduce a wafer production cost.

Therefore, the second embodiment achieves an effect that it is possible to provide the wire electrical discharge machining apparatus 1000 capable of accurately detecting a defect caused by positional displacement of the wire electrode 1. In addition, the second embodiment achieves an effect that it is possible to make the plate thickness of the thin plates to be collectively cut from the workpiece W uniform. Moreover, the second embodiment achieves an effect that it is possible to prevent damage to the devices included in the wire electrical discharge machining apparatus 1000 caused by the wire electrode 1 in the short-circuit state.

Next, each hardware configuration of a control unit 80 according to the first and second embodiments will be described. The control unit 80 according to the first and second embodiments corresponds to each of the control unit 300 and the wire extension state monitoring unit 400 in the first and second embodiments, and the wire contact machining state monitoring unit 500 in the second embodiment. Each function of the control unit 80 according to the first and second embodiments is realized by a processing circuitry. The processing circuitry may be dedicated hardware or a processing device that executes a program stored in a storage device.

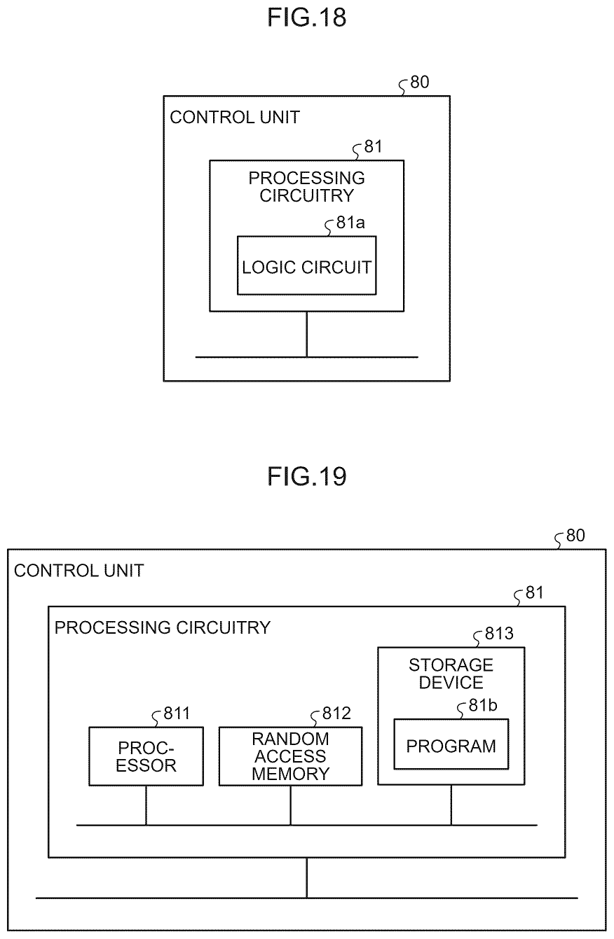

In a case where the processing circuitry is dedicated hardware, the processing circuitry corresponds to a single circuit, a composite circuit, a programmed processor, a parallel programmed processor, an application specific integrated circuit, a field programmable gate array, or a combination thereof. FIG. 18 is a diagram illustrating a configuration in which each function of the control unit according to the first and second embodiments is realized by hardware. A logic circuit 81a for realizing functions of the control unit 80 is incorporated in a processing circuitry 81.

In a case where the processing circuitry 81 is a processing device, the functions of the control unit 80 are realized by software, firmware, or a combination of software and firmware.

FIG. 19 is a diagram illustrating a configuration in which each function of the control unit according to the first and second embodiments is realized by software. The processing circuitry 81 includes a processor 811 that executes a program 81b, a random access memory 812 used as a work area by the processor 811, and a storage device 813 that stores the program 81b. The functions of the control unit 80 are realized by the processor 811 expanding and executing the program 81b stored in the storage device 813 on the random access memory 812. The software or the firmware is described in a programming language and stored in the storage device 813. As the processor 811, a central processing unit can be exemplified, but there is no limitation thereto. As the storage device 813, a semiconductor memory such as a random access memory (RAM), a read only memory (ROM), a flash memory, an erasable programmable read only memory (EPROM), or an electrically erasable programmable read only memory (EEPROM (registered trademark)) can be applied. The semiconductor memory may be a nonvolatile memory or a volatile memory. In addition to the semiconductor memory, a magnetic disk, a flexible disk, an optical disk, a compact disc, a mini disk, or a digital versatile disc (DVD) can be applied as the storage device 813. Note that the processor 811 may output data such as a calculation result to the storage device 813 and store the data therein, or may store the data in an auxiliary storage device (not illustrated) via the random access memory 812. By integrating the processor 811, the random access memory 812, and the storage device 813 in one chip, the functions of the control unit 80 can be realized by a microcomputer.

The processing circuitry 81 realizes the functions of the control unit 80 by reading and executing the program 81b stored in the storage device 813. It can also be said that the program 81b causes a computer to execute procedures and methods for realizing the functions of the control unit 80.

The processing circuitry 81 may realize a part of the functions of the control unit 80 by dedicated hardware, and realize another part of the functions of the control unit 80 by software or firmware.

Thus, the processing circuitry 81 can realize the above-described functions by hardware, software, firmware, or a combination thereof.

The configurations described in the above embodiments are merely examples and can be combined with other known technology, the embodiments can be combined with each other, and part of the configurations can be omitted or modified without departing from the gist thereof.

### REFERENCE SIGNS LIST

1 wire electrode; 1a parallel wire part; 1b cutting wire part; 2, 2a, 2b, 2c, 2d guide roller; 2e, 51c wire guide groove; 3, 3a, 3b bobbin; 4a, 4 4b damping guide roller; 5 machining power supply; 6a, 6b power feed contact unit; 7a, 7b nozzle; 7c machining fluid ejection hole; 8a, 8b bobbin rotation control device; 9a, 9b traverse control device; 10 cutting feed stage; 11 power feed contact; 12 a, 12 b power supply line; 31 machining control device; 32 electrical discharge waveform control device; 34 cutting stage drive control device; 35 wire running control device; 42 workpiece fixing plate; 43 plane; 51a, 51b wire parallel guide roller; 51al upper end portion; 51a2 rotation shaft; 51d outer peripheral surface; 52a, 52b parallel wire extension position measurement unit; 52a1, 55al upper surface; 53 wire guide groove detachment detection unit; 54 wire state determination unit; 55a, 55b guide roller holder; 62 machining fluid supply pipe; 70 thin plate machining stabilization unit; 71, 71a, 71b machining fluid flow rectifying plate; 72 workpiece retaining unit; 74 wire contact detection power supply; 75a, 75b nozzle contact detection device; 76 wire contact detection circuit switching device; 77 wire contact determination device; 100 machining mechanism unit; 101, 102, 103 arrow; 200 power feed unit; 300 control unit; 400 wire extension state monitoring unit; 500 wire contact machining state monitoring unit; 1000 wire electrical discharge machining apparatus; L, L1, L2, L3 distance; P1 machining power application time; P2 machining power off time; W workpiece; Wz cut groove.

1. A wire electrical discharge machining apparatus that generates electrical discharge between a plurality of cutting wire parts that are running and a workpiece to perform electrical discharge machining on the workpiece with energy generated by the electrical discharge, and simultaneously cuts a plurality of wafers from the workpiece, the wire electrical discharge machining apparatus comprising:
a wire electrode including the plurality of the cutting wire parts spaced apart from each other in parallel and including a portion facing the workpiece;
power feed circuitry to generate electrical discharge between the plurality of cutting wire parts and the workpiece;
a pair of wire parallel guide rollers disposed on both sides of the workpiece so as to sandwich the workpiece, in each of which a plurality of wire guide grooves are formed on an outer peripheral side surface thereof at equal intervals, the plurality of wire guide grooves causing the plurality of cutting wire parts that are running to fit therein and restricting movement of the plurality of cutting wire parts;
parallel wire extension position measurement circuitry to measure a distance between a measurement reference surface set parallel to a virtual plane including the plurality of cutting wire parts and the wire electrode constituting the plurality of cutting wire parts;
wire guide groove detachment detection circuitry to detect occurrence of a change in the distance on a basis of a measurement result obtained by the parallel wire extension position measurement circuitry;
wire state determination circuitry to determine whether it is a wire detachment state where at least one of the cutting wire parts is detached from the wire guide groove or a wire contact state where all the cutting wire parts are in contact with the wire guide grooves, on a basis of a detection result obtained by the wire guide groove detachment detection circuitry; and
machining control circuitry to control stop or continuation of electrical discharge machining on a basis of a determination result obtained by the wire state determination circuitry.

2. The wire electrical discharge machining apparatus according to claim 1, wherein
the parallel wire extension position measurement circuitry includes at least one of an eddy current type displacement sensor, a capacitive displacement sensor, a conduction-sensitive sensor, and a touch-sensitive displacement sensor, and measures the distance.

3. The wire electrical discharge machining apparatus according to claim 1, wherein
the machining control circuitry stops electrical discharge machining in a case where the wire state determination circuitry determines that it is the wire detachment state.

4. The wire electrical discharge machining apparatus according to claim 1, wherein the power feed circuitry comprises a machining power supply and a power feed contact connected to the cutting wire part to supply power from the machining power supply to the cutting wire part,
the wire electrical discharge machining apparatus comprises:
a nozzle disposed at a position above the plurality of cutting wire parts to supply a machining fluid to a gap between the cutting wire part and the workpiece, in a state where the plurality of cutting wire parts are sandwiched between the wire parallel guide roller and the nozzle and in a state where the nozzle is spaced apart from the plurality of cutting wire parts; and
wire contact detection circuitry to detect contact between the nozzle and the cutting wire part on a basis of a potential difference between the nozzle and the power feed contact, and
the machining control circuitry stops electrical discharge machining in a case where contact between the nozzle and the cutting wire part is detected in the wire contact detection circuitry.

5. The wire electrical discharge machining apparatus according to claim 4, comprising:
a cutting feed stage to change relative positions of the workpiece and the cutting wire part, wherein
the machining control circuitry stops power supply to all the cutting wire parts and stops electrical discharge machining in a case where contact between the nozzle and the cutting wire part is detected and a retreat operation for eliminating short circuit is not performed in which a feeding direction of the cutting feed stage is reversed from a cutting progression direction of the workpiece.

6. A wire electrical discharge machining method that generates electrical discharge between a plurality of cutting wire parts that are running and a workpiece to perform electrical discharge machining on the workpiece with energy generated by the electrical discharge, and simultaneously cuts a plurality of wafers from the workpiece, the wire electrical discharge machining method comprising:
measuring a distance between a measurement reference surface set parallel to a virtual plane including the plurality of cutting wire parts and a wire electrode constituting the plurality of cutting wire parts;
detecting occurrence of a change in the distance on a basis of a measurement result obtained in the measuring the distance;
determining whether it is a wire detachment state where at least one of the cutting wire parts is detached from the wire guide groove or a wire contact state where all the cutting wire parts are in contact with the wire guide grooves, on a basis of a detection result obtained in the detecting occurrence of the change; and
controlling stop or continuation of electrical discharge machining on a basis of a determination result obtained in the determining whether it is the wire detachment state or the wire contact state.

7. The wire electrical discharge machining method according to claim 6, wherein
in the controlling stop or continuation of electrical discharge machining, power supply to all the cutting wire parts is stopped and electrical discharge machining is stopped in a case where contact between a nozzle and the cutting wire part is detected and a retreat operation for eliminating short circuit is not performed in which a feeding direction of a cutting feed stage that changes relative positions of the workpiece and the cutting wire part is reversed from a cutting progression direction of the workpiece, the nozzle being disposed at a position above the plurality of cutting wire parts and supplying a machining fluid to a gap between the cutting wire part and the workpiece, in a state where the plurality of cutting wire parts are sandwiched between a pair of wire parallel guide rollers and the nozzle and in a state where the nozzle is spaced apart from the plurality of cutting wire parts, the pair of wire parallel guide rollers being disposed on both sides of the workpiece so as to sandwich the workpiece, a plurality of wire guide grooves being formed on an outer peripheral side surface of each of the pair of wire parallel guide rollers at equal intervals, the plurality of wire guide grooves causing the plurality of cutting wire parts to fit therein and restricting movement of the plurality of cutting wire parts.

8. A wafer manufacturing method, wherein
a plurality of wafers are simultaneously cut out from the workpiece by the wire electrical discharge machining method according to claim 6.

9. The wafer manufacturing method according to claim 8, wherein
the workpiece is a semiconductor ingot, and
the wafer is a semiconductor wafer.

10. The wire electrical discharge machining apparatus according to claim 2, wherein
the machining control circuitry stops electrical discharge machining in a case where the wire state determination circuitry determines that it is the wire detachment state.

11. The wire electrical discharge machining apparatus according to claim 2, wherein
the power feed circuitry comprises a machining power supply and a power feed contact connected to the cutting wire part to supply power from the machining power supply to the cutting wire part,
the wire electrical discharge machining apparatus comprises:
a nozzle disposed at a position above the plurality of cutting wire parts to supply a machining fluid to a gap between the cutting wire part and the workpiece, in a state where the plurality of cutting wire parts are sandwiched between the wire parallel guide roller and the nozzle and in a state where the nozzle is spaced apart from the plurality of cutting wire parts; and
wire contact detection circuitry to detect contact between the nozzle and the cutting wire part on a basis of a potential difference between the nozzle and the power feed contact, and
the machining control circuitry stops electrical discharge machining in a case where contact between the nozzle and the cutting wire part is detected in the wire contact detection circuitry.

12. The wire electrical discharge machining apparatus according to claim 3, wherein
the power feed circuitry comprises a machining power supply and a power feed contact connected to the cutting wire part to supply power from the machining power supply to the cutting wire part,
the wire electrical discharge machining apparatus comprises:
a nozzle disposed at a position above the plurality of cutting wire parts to supply a machining fluid to a gap between the cutting wire part and the workpiece, in a state where the plurality of cutting wire parts are sandwiched between the wire parallel guide roller and the nozzle and in a state where the nozzle is spaced apart from the plurality of cutting wire parts; and
wire contact detection circuitry to detect contact between the nozzle and the cutting wire part on a basis of a potential difference between the nozzle and the power feed contact, and
the machining control circuitry stops electrical discharge machining in a case where contact between the nozzle and the cutting wire part is detected in the wire contact detection circuitry.

13. The wire electrical discharge machining apparatus according to claim 10, wherein
the power feed circuitry comprises a machining power supply and a power feed contact connected to the cutting wire part to supply power from the machining power supply to the cutting wire part,
the wire electrical discharge machining apparatus comprises:
a nozzle disposed at a position above the plurality of cutting wire parts to supply a machining fluid to a gap between the cutting wire part and the workpiece, in a state where the plurality of cutting wire parts are sandwiched between the wire parallel guide roller and the nozzle and in a state where the nozzle is spaced apart from the plurality of cutting wire parts; and
wire contact detection circuitry to detect contact between the nozzle and the cutting wire part on a basis of a potential difference between the nozzle and the power feed contact, and
the machining control circuitry stops electrical discharge machining in a case where contact between the nozzle and the cutting wire part is detected in the wire contact detection circuitry.

14. The wire electrical discharge machining apparatus according to claim 11, comprising:
a cutting feed stage to change relative positions of the workpiece and the cutting wire part, wherein
the machining control circuitry stops power supply to all the cutting wire parts and stops electrical discharge machining in a case where contact between the nozzle and the cutting wire part is detected and a retreat operation for eliminating short circuit is not performed in which a feeding direction of the cutting feed stage is reversed from a cutting progression direction of the workpiece.

15. The wire electrical discharge machining apparatus according to claim 12, comprising:
a cutting feed stage to change relative positions of the workpiece and the cutting wire part, wherein
the machining control circuitry stops power supply to all the cutting wire parts and stops electrical discharge machining in a case where contact between the nozzle and the cutting wire part is detected and a retreat operation for eliminating short circuit is not performed in which a feeding direction of the cutting feed stage is reversed from a cutting progression direction of the workpiece.

16. The wire electrical discharge machining apparatus according to claim 13, comprising:
a cutting feed stage to change relative positions of the workpiece and the cutting wire part, wherein
the machining control circuitry stops power supply to all the cutting wire parts and stops electrical discharge machining in a case where contact between the nozzle and the cutting wire part is detected and a retreat operation for eliminating short circuit is not performed in which a feeding direction of the cutting feed stage is reversed from a cutting progression direction of the workpiece.

17. A wafer manufacturing method, wherein
a plurality of wafers are simultaneously cut out from the workpiece by the wire electrical discharge machining method according to claim 7.

18. The wafer manufacturing method according to claim 17, wherein
the workpiece is a semiconductor ingot, and
the wafer is a semiconductor wafer.
